(19) United States
(12) Patent Application Publication
(10) Pub. No.: US 2024/0170515 A1
(43) Pub. Date: May 23, 2024

(54) PHOTODETECTION DEVICE AND ELECTRONIC DEVICE

(71) Applicant: SONY SEMICONDUCTOR SOLUTIONS CORPORATION, Kanagawa (JP)

(72) Inventors: Yoshiyuki OHBA, Kumamoto (JP); Shinichiro NOUDO, Kanagawa (JP); Yoshinori KATO, Kumamoto (JP); Yasushi MARUYAMA, Kanagawa (JP)

(73) Assignee: SONY SEMICONDUCTOR SOLUTIONS CORPORATION, Kanagawa (JP)

(21) Appl. No.: 18/551,648

(22) PCT Filed: Mar. 9, 2022
(86) PCT No.: PCT/JP2022/010154

§ 371 Date: Sep. 21, 2023

(30) Foreign Application Priority Data
Mar. 31, 2021 (JP) 2021-062383

(51) Int. Cl. H01L 27/146; G02B 5/20

(52) U.S. Cl. CPC H01L 27/14621; H01L 27/14645; H01L 27/14685; G02B 5/20

(57) ABSTRACT

An object of the present technology is to provide a photodetection device in which occurrence of stress migration is suppressed. A photodetection device includes: a semiconductor layer including a photoelectric conversion unit; an optical element that includes a base material and an opening array formed in the base material, supplies light selected by the opening array to the photoelectric conversion unit, and is arranged so as to overlap the photoelectric conversion unit in plan view, in which the base material has a stacked structure including a first conductor layer, an intermediate layer, and a second conductor layer in this order from the semiconductor layer side.

### TECHNICAL FIELD

The present technology (technology according to the present disclosure) relates to a photodetection device and an electronic device, and particularly relates to a photodetection device and an electronic device having an optical element including a conductor layer.

### BACKGROUND ART

A multispectral sensor that detects light in a narrow band using a surface plasmon resonance phenomenon is well known from, for example, Patent Document 1. Vibration of electrons called surface plasmon induced by light applied to a surface of a metal thin film having periodic apertures passes through the apertures. Since the energy of the surface plasmon is sufficiently small such as several tens to several hundreds nm, even a component having a wavelength longer than the cutoff wavelength of the apertures (waveguides) can be transmitted through the apertures. The surface plasmon transmitted through the apertures is again converted into light at the opposite metal surface and emitted. A surface plasmonic filter controls the spectroscopy of the transmitted light by changing the interval and diameter of the holes.

Furthermore, a polarization sensor provided with a wire grid polarizer (WGP) is known from, for example, Patent Document 2. In the reflective wire grid polarizer, the conductor is processed to have a line-and-space shape. In a case where the vibration direction of the electric field of light is the same direction as that of the polarizer, free electrons in the conductor follow the electric field such that the electric field becomes zero, and the light is canceled out by the reflected wave generated by the movement and cannot be transmitted. On the other hand, in a case where the vibration direction of the electric field of the light is orthogonal to the polarizer, free electrons in the conductor cannot follow the electric field and do not generate a reflected wave, so that the light is transmitted. In this way, it is possible to selectively transmit only light in which the vibration direction of the electric field is perpendicular to the strip-shaped conductor of the polarizer.

In addition, a guided mode resonance (GMR) filter is an optical filter capable of transmitting only light in a narrow wavelength band (narrow band) by combining a diffraction grating and a clad-core structure (for example, Patent Document 3). It utilizes the resonance between the guided mode generated in the waveguide and the diffracted light, and is characterized in that light utilization efficiency is high and a sharp resonance spectrum is obtained.

### CITATION LIST

### Patent Document

Patent Document 1: Japanese Patent Application Laid-Open No. 2018-98641
Patent Document 2: Japanese Patent Application Laid-Open No. 2017-76683
Patent Document 3: Japanese Patent Application Laid-Open No. 2018-195908

### SUMMARY OF THE INVENTION

### Problems to be Solved by the Invention

The above-described optical element includes a conductor layer. Therefore, stress migration may occur. An object of the present technology is to provide a photodetection device and an electronic device in which occurrence of stress migration is suppressed.

### Solutions to Problems

A photodetection device according to an aspect of the present technology includes: a semiconductor layer including a photoelectric conversion unit; an optical element that includes a base material and an opening array formed in the base material, supplies light selected by the opening array to the photoelectric conversion unit, and is arranged so as to overlap the photoelectric conversion unit in plan view, the base material has a stacked structure including a first conductor layer, an intermediate layer, and a second conductor layer in this order from the semiconductor layer side.

An electronic device according to an aspect of the present technology includes the photodetection device and an optical system that forms an image of image light from a subject on the photodetection device.

A photodetection device according to another aspect of the present technology includes: a semiconductor layer including a photoelectric conversion unit; and an optical element that includes a base material including a conductor layer and an opening array formed in the base material, supplies light selected by the opening array to the photoelectric conversion unit, and is arranged to overlap the photoelectric conversion unit in plan view, the base material includes a first region in which the opening array is provided and a second region in which the opening array is not provided in plan view, and the base material has a thickness larger in the second region than in the first region.

An electronic device according to another aspect of the present technology includes the photodetection device and an optical system that forms an image of image light from a subject on the photodetection device.

### BRIEF DESCRIPTION OF DRAWINGS

FIG. 1 is a chip layout diagram illustrating a configuration example of a photodetection device according to a first embodiment of the present technology.

FIG. 2 is a block diagram illustrating the configuration example of the photodetection device according to the first embodiment of the present technology.

FIG. 3 is an equivalent circuit diagram of a pixel of the photodetection device according to the first embodiment of the present technology.

FIG. 4 is a vertical cross-sectional view illustrating a cross-sectional configuration of a photodetection device according to the first embodiment of the present technology.

FIG. 5A is a plan view illustrating an example of a planar configuration of a plasmonic filter included in the photodetection device according to the first embodiment of the present technology.

FIG. 5B is a vertical cross-sectional view illustrating a cross-sectional configuration of the plasmonic filter when viewed in a cross-sectional view taken along line C-C in FIG. 5A.

FIG. 6A is a process cross-sectional view illustrating a method of manufacturing the photodetection device according to the first embodiment of the present technology.

FIG. 6B is a process cross-sectional view subsequent to FIG. 6A.

FIG. 6C is a process cross-sectional view subsequent to FIG. 6B.

FIG. 6D is a process cross-sectional view subsequent to FIG. 6C.

FIG. 6E is a process cross-sectional view subsequent to FIG. 6D.

FIG. 6F is a process cross-sectional view subsequent to FIG. 6E.

FIG. 7A is a process cross-sectional view illustrating a general method of manufacturing an aluminum wiring.

FIG. 7B is a process cross-sectional view subsequent to FIG. 7A.

FIG. 7C is a process cross-sectional view subsequent to FIG. 7B.

FIG. 7D is a process cross-sectional view subsequent to FIG. 7C.

FIG. 7E is a view illustrating a void generated in a general aluminum wiring.

FIG. 7F is a view illustrating an example of a case where a conventional plasmonic filter is affected by stress migration.

FIG. 8 is a view illustrating an example of a case where the plasmonic filter included in the photodetection device according to the first embodiment of the present technology is affected by stress migration.

FIG. 9 is a vertical cross-sectional view illustrating a cross-sectional configuration of a plasmonic filter included in a photodetection device according to another mode of the first embodiment of the present technology.

FIG. 10 is a vertical cross-sectional view illustrating a cross-sectional configuration of a plasmonic filter included in a photodetection device according to Modification 1 of the first embodiment of the present technology.

FIG. 11 is a vertical cross-sectional view illustrating a cross-sectional configuration of a plasmonic filter included in a photodetection device according to Modification 2 of the first embodiment of the present technology.

FIG. 12A is a plan view illustrating an example of a planar configuration of a wire grid polarizer included in a photodetection device according to a second embodiment of the present technology.

FIG. 12B is a vertical cross-sectional view illustrating a part of a cross-sectional configuration of the wire grid polarizer when viewed in a cross-sectional view taken along line C-C in FIG. 12A.

FIG. 13A is a plan view illustrating an example of a planar configuration of a GMR color filter included in a photodetection device according to a third embodiment of the present technology.

FIG. 13B is a vertical cross-sectional view illustrating a cross-sectional configuration of the GMR color filter when viewed in a cross-sectional view taken along line C-C in FIG. 13A.

FIG. 14 is a plan view illustrating an example of a planar configuration of a GMR color filter included in a photodetection device according to another mode of the third embodiment of the present technology.

FIG. 15 is a vertical cross-sectional view illustrating a cross-sectional configuration of a photodetection device according to a fourth embodiment of the present technology.

FIG. 16 is a vertical cross-sectional view illustrating an example of a cross-sectional configuration of an element isolation unit included in a photodetection device according to a fifth embodiment of the present technology.

FIG. 17 is a plan view illustrating an example of a planar configuration of the element isolation unit included in the photodetection device according to the fifth embodiment of the present technology.

FIG. 18A is a process cross-sectional view illustrating a method of manufacturing the element isolation unit included in the photodetection device according to the fifth embodiment of the present technology.

FIG. 18B is a process cross-sectional view subsequent to FIG. 18A.

FIG. 18C is a process cross-sectional view subsequent to FIG. 18B.

FIG. 18D is a process cross-sectional view subsequent to FIG. 18C.

FIG. 18E is a process cross-sectional view subsequent to FIG. 18D.

FIG. 19 is a plan view illustrating an example of a planar configuration of the element isolation unit included in the photodetection device according to the fifth embodiment of the present technology.

FIG. 20 is a vertical cross-sectional view illustrating an example of a cross-sectional configuration of an element isolation unit included in a photodetection device according to Modification 1 of the fifth embodiment of the present technology.

FIG. 21 is a vertical cross-sectional view illustrating an example of a cross-sectional configuration of an element isolation unit included in a photodetection device according to Modification 2 of the fifth embodiment of the present technology.

FIG. 22 is a vertical cross-sectional view illustrating a cross-sectional configuration of a photodetection device according to a sixth embodiment of the present technology.

FIG. 23A is a plan view illustrating an example of a planar configuration of a plasmonic filter included in a photodetection device according to a seventh embodiment of the present technology.

FIG. 23B is a vertical cross-sectional view illustrating a cross-sectional configuration of the plasmonic filter when viewed in a cross-sectional view taken along line C-C in FIG. 23A.

FIG. 23C is a plan view illustrating an example of a planar configuration of the plasmonic filter included in the photodetection device according to the seventh embodiment of the present technology.

FIG. 24A is a process cross-sectional view illustrating a method of manufacturing the photodetection device according to the seventh embodiment of the present technology.

FIG. 24B is a process cross-sectional view subsequent to FIG. 24A.

FIG. 24C is a process cross-sectional view subsequent to FIG. 24B.

FIG. 24D is a process cross-sectional view subsequent to FIG. 24C.

FIG. 24E is a process cross-sectional view subsequent to FIG. 24D.

FIG. 25 is a vertical cross-sectional view illustrating a cross-sectional configuration of a plasmonic filter included in a photodetection device according to another mode of the seventh embodiment of the present technology.

FIG. 26 is a vertical cross-sectional view illustrating a cross-sectional configuration of a plasmonic filter included in a photodetection device according to Modification 1 of the seventh embodiment of the present technology.

FIG. 27A is a process cross-sectional view illustrating a method of manufacturing the photodetection device according to Modification 1 of the seventh embodiment of the present technology.

FIG. 27B is a process cross-sectional view subsequent to FIG. 27A.

FIG. 27C is a process cross-sectional view subsequent to FIG. 27B.

FIG. 27D is a process cross-sectional view subsequent to FIG. 27C.

FIG. 27E is a process cross-sectional view subsequent to FIG. 27D.

FIG. 27F is a process cross-sectional view subsequent to FIG. 27E.

FIG. 28 is a vertical cross-sectional view illustrating a cross-sectional configuration of a plasmonic filter included in a photodetection device according to Modification 2 of the seventh embodiment of the present technology.

FIG. 29A is a process cross-sectional view illustrating a method of manufacturing the photodetection device according to Modification 2 of the seventh embodiment of the present technology.

FIG. 29B is a process cross-sectional view subsequent to FIG. 29A.

FIG. 29C is a process cross-sectional view subsequent to FIG. 29B.

FIG. 29D is a process cross-sectional view subsequent to FIG. 29C.

FIG. 29E is a process cross-sectional view subsequent to FIG. 29D.

FIG. 29F is a process cross-sectional view subsequent to FIG. 29E.

FIG. 30 is a vertical cross-sectional view illustrating a cross-sectional configuration of a plasmonic filter included in a photodetection device according to Modification 3 of the seventh embodiment of the present technology.

FIG. 31A is a plan view illustrating an example of a planar configuration of a wire grid polarizer included in a photodetection device according to Modification 4 of the seventh embodiment of the present technology.

FIG. 31B is a vertical cross-sectional view illustrating a cross-sectional configuration of the wire grid polarizer when viewed in a cross-sectional view taken along line C-C in FIG. 31A.

FIG. 32 is a vertical cross-sectional view illustrating a cross-sectional configuration of a plasmonic filter included in a photodetection device according to Modification 5 of the seventh embodiment of the present technology.

FIG. 33 is a diagram illustrating a schematic configuration of an electronic device according to an eighth embodiment of the present technology.

### MODE FOR CARRYING OUT THE INVENTION

Preferred embodiments for implementing the present technology will be described with reference to the drawings. Note that embodiments hereinafter described each illustrate an example of a representative embodiment of the present technology, and the scope of the present technology is not narrowed by them.

In the following description of the drawings, the same or similar parts are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it is needless to say that the drawings include portions having different dimensional relationships and ratios.

Furthermore, the first to eighth embodiments described below each illustrate an example of a device and a method for embodying the technical idea of the present technology, and the technical idea of the present technology does not limit the material, shape, structure, arrangement, and the like of components to the following. Various modifications can be made to the technical idea of the present technology within the technical scope defined by the claims described in the claims.

The description is given in the following order.
1. First Embodiment
2. Second Embodiment
3. Third Embodiment
4. Fourth Embodiment
5. Fifth Embodiment
6. Sixth Embodiment
7. Seventh Embodiment
8. Eighth Embodiment

### FIRST EMBODIMENT

In the first embodiment, an example in which the present technology is applied to a photodetection device that is a back-illuminated complementary metal oxide semiconductor (CMOS) image sensor will be described.

<<Overall Configuration of Photodetection Device>>

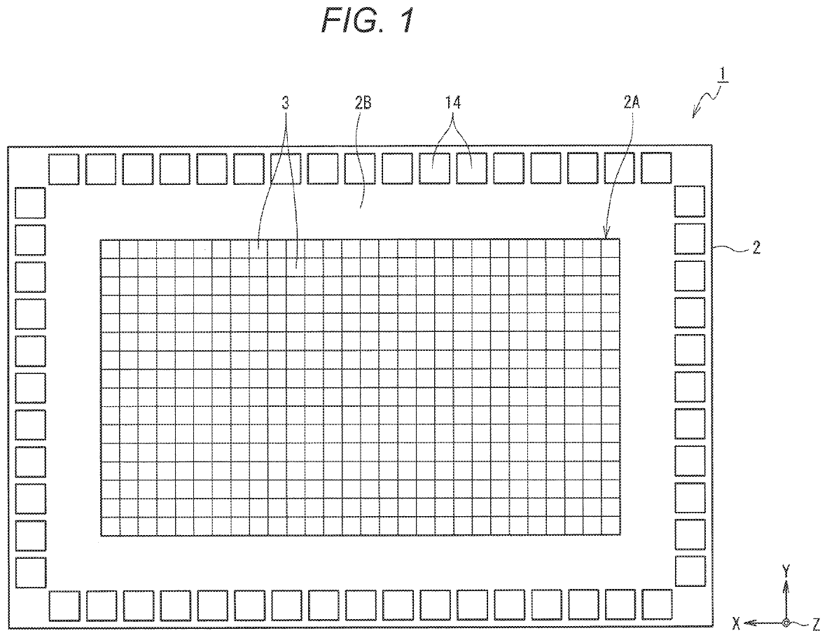

First, the overall configuration of a photodetection device 1 will be described. As illustrated in FIG. 1, the photodetection device 1 according to the first embodiment of the present technology mainly includes a semiconductor chip 2 having a rectangular two-dimensional planar shape in plan view. That is, the photodetection device 1 is mounted on the semiconductor chip 2. As illustrated in FIG. 33, the photodetection device 1 receives image light (incident light 106) from a subject through an optical system (optical lens) 102, converts an amount of the incident light 106 formed as an image on an imaging surface into an electrical signal for each pixel, and outputs the electrical signal as a pixel signal.

As illustrated in FIG. 1, the semiconductor chip 2 on which the photodetection device 1 is mounted includes, in a two-dimensional plane having the X direction and the Y direction intersecting each other, a rectangular pixel region 2A provided in a central portion, and a peripheral region 2B provided outside the pixel region 2A so as to surround the pixel region 2A.

The pixel region 2A is, for example, a light receiving surface that receives light condensed by the optical system 102 illustrated in FIG. 33. Then, in the pixel region 2A, a plurality of pixels 3 is arranged in a matrix on a two-dimensional plane having the X direction and the Y direction. In other words, the pixels 3 are repeatedly arranged in each of the X direction and the Y direction intersecting each other on the two-dimensional plane. Note that in the present embodiment, as an example, the X direction and the Y direction are orthogonal to each other. Furthermore, a direction orthogonal to both the X direction and the Y direction is a Z direction (thickness direction).

As illustrated in FIG. 1, a plurality of bonding pads 14 is arranged in the peripheral region 2B. The plurality of bonding pads 14 is arranged, for example, along the four sides on the two-dimensional plane of the semiconductor chip 2. Each of the plurality of bonding pads 14 is an input-output terminal used when the semiconductor chip 2 is electrically connected to an external device.

<Logic Circuit>

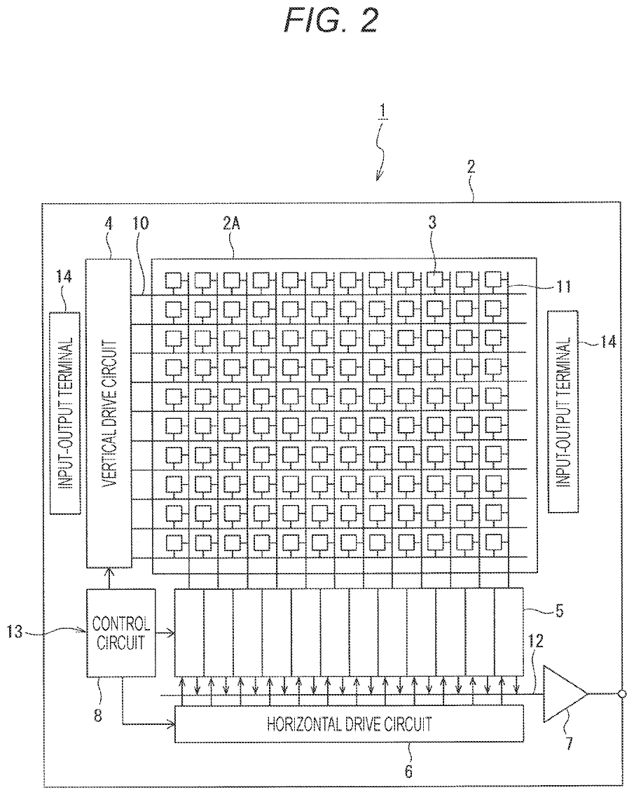

As illustrated in FIG. 2, the semiconductor chip 2 includes a logic circuit 13 including a vertical drive circuit 4, a column signal processing circuit 5, a horizontal drive circuit 6, an output circuit 7, a control circuit 8, and the like. The logic circuit 13 includes, for example, a complementary MOS (CMOS) circuit including an n-channel conductivity-type metal oxide semiconductor field effect transistor (MOSFET) and a p-channel conductive MOSFET as field effect transistors.

The vertical drive circuit 4 includes, for example, a shift register. The vertical drive circuit 4 sequentially selects desired pixel drive lines 10, supplies a pulse for driving the pixels 3 to the selected pixel drive lines 10, and drives the pixels 3 on a row-by-row basis. That is, the vertical drive circuit 4 selectively scans the pixels 3 in the pixel region 2A sequentially in a vertical direction on a row-by-row basis, and supplies a pixel signal from each pixel 3 based on a signal charge generated according to the amount of received light by a photoelectric conversion element of the pixel 3 to the column signal processing circuit 5 through a vertical signal line 11.

The column signal processing circuit 5 is arranged, for example, on every column of the pixels 3 and performs signal processing such as noise removal on signals output from the pixels 3 of one row, for every pixel column. For example, the column signal processing circuit 5 performs signal processing such as correlated double sampling (CDS) for removing pixel-specific fixed pattern noise and analog digital (AD) conversion. A horizontal selection switch (not illustrated) is provided at an output stage of the column signal processing circuit 5 so as to be connected with a horizontal signal line 12.

The horizontal drive circuit 6 includes, for example, a shift register. The horizontal drive circuit 6 sequentially outputs horizontal scanning pulses to the column signal processing circuits 5 to sequentially select the column signal processing circuits 5 to cause each of the column signal processing circuits 5 to output the pixel signal subjected to the signal processing to the horizontal signal line 12.

The output circuit 7 performs signal processing on pixel signals sequentially supplied from the column signal processing circuits 5 through the horizontal signal line 12 and outputs the pixel signals. As the signal processing, for example, buffering, black level adjustment, column variation correction, various types of digital signal processing, and the like can be used.

The control circuit 8 generates a clock signal and a control signal, which are references for operations of the vertical drive circuit 4, the column signal processing circuit 5, the horizontal drive circuit 6, and the like, on the basis of a vertical synchronization signal, a horizontal synchronization signal, and a master clock signal. Then, the control circuit 8 outputs the clock signal and the control signal thus generated to the vertical drive circuit 4, the column signal processing circuit 5, the horizontal drive circuit 6, and the like.

<Pixel>

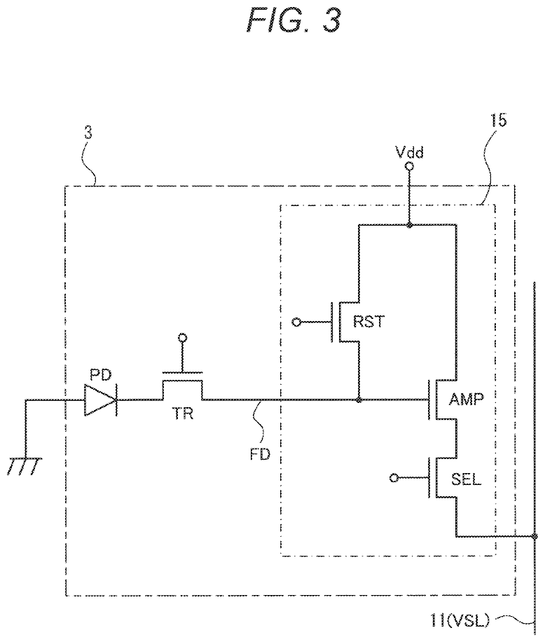

FIG. 3 is an equivalent circuit diagram illustrating a configuration example of the pixel 3. The pixel 3 includes a photoelectric conversion element PD, a charge accumulation region (floating diffusion) FD that accumulates (holds) signal charges obtained by photoelectrical conversion by the photoelectric conversion element PD, and a transfer transistor TR that transfers the signal charges obtained by photoelectrical conversion by the photoelectric conversion element PD to the charge accumulation region FD. Furthermore, the pixel 3 includes a reading circuit 15 electrically connected to the charge accumulation region FD.

The photoelectric conversion element PD generates a signal charge corresponding to the amount of received light. The photoelectric conversion element PD also temporarily accumulates (holds) the generated signal charge. The photoelectric conversion element PD has a cathode side electrically connected to the source region of the transfer transistor TR, and an anode side electrically connected to a reference potential line (for example, ground). As the photoelectric conversion element PD, for example, a photodiode is used.

The drain region of the transfer transistor TR is electrically connected to the charge accumulation region FD. The gate electrode of the transfer transistor TR is electrically connected to the transfer transistor drive line of the pixel drive line 10 (see FIG. 2).

The charge accumulation region FD temporarily accumulates and holds the signal charge transferred from the photoelectric conversion element PD via the transfer transistor TR.

The reading circuit 15 reads the signal charge accumulated in the charge accumulation region FD, and outputs a pixel signal based on the signal charge. Although not limited thereto, the reading circuit 15 includes, for example, an amplification transistor AMP, a selection transistor SEL, and a reset transistor RST, as pixel transistors. These transistors (AMP, SEL, RST) are configured as, for example, a MOSFET including a gate insulating film including a silicon oxide film (SiO₂ film), a gate electrode, and a pair of main electrode regions functioning as a source region and a drain region. In addition, these transfer transistors may be formed as a metal insulator semiconductor FET (MISFET) in which the gate insulating film is a silicon nitride film (Si₃N₄ film) or a stacked film including a silicon nitride film and a silicon oxide film, or the like.

The amplification transistor AMP has a source region electrically connected to the drain region of the selection transistor SEL, and a drain region electrically connected to the power supply line Vdd and the drain region of the reset transistor. Then, the gate electrode of the amplification transistor AMP is electrically connected to the charge accumulation region FD and the source region of the reset transistor RST.

The selection transistor SEL has a source region electrically connected to the vertical signal line 11 (VSL), and a drain electrically connected to the source region of the amplification transistor AMP. Furthermore, a gate electrode of the selection transistor SEL is electrically connected to a selection transistor drive line of the pixel drive line 10 (see FIG. 2).

The reset transistor RST has a source region electrically connected to the charge accumulation region FD and the gate electrode of the amplification transistor AMP, and a drain region electrically connected to a power supply line Vdd and the drain region of the amplification transistor AMP. The gate electrode of the reset transistor RST is electrically connected to a reset transistor drive line of the pixel drive line 10 (see FIG. 2).

<<Specific Configuration of Photodetection Device>>

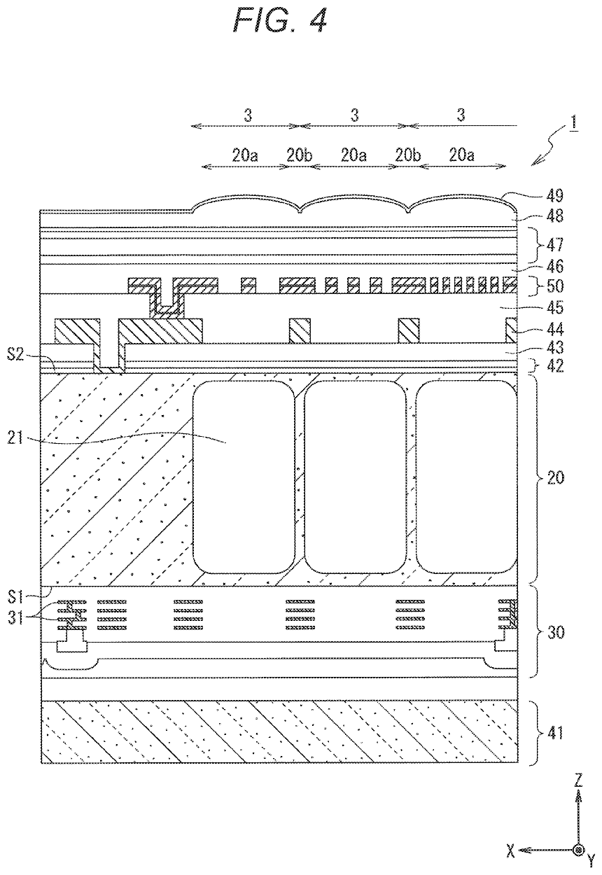

Next, a specific configuration of the photodetection device 1 will be described with reference to FIG. 4.

<Stacked Structure of Photodetection Device>

As illustrated in FIG. 4, the photodetection device 1 includes a semiconductor layer 20 having a first surface S1 and a second surface S2 located on opposite sides to each other. The semiconductor layer 20 includes, for example, a silicon substrate. More specifically, the semiconductor layer 20 includes a single-crystal silicon substrate of a second conductivity-type, for example, p-type. Furthermore, the photodetection device 1 includes a wiring layer 30 and a support substrate 41 sequentially stacked in this order on the first surface S1 side of the semiconductor layer 20. Furthermore, in the photodetection device 1, a fixed charge film 42, an insulating layer 43, a light-shielding metal 44, an insulating layer 45, a plasmonic filter 50, an insulating layer 46, a passivation film 47, and an on-chip lens 48 are stacked in this order on the second surface S2 side of the semiconductor layer 20. Furthermore, the first surface S1 of the first semiconductor layer 20 may be referred to as an element formation surface or a main surface, and the second surface S2 side may be referred to as a light incident surface or a back surface.

<Photoelectric Conversion Region>

As illustrated in FIG. 4, the semiconductor layer 20 has island-shaped photoelectric conversion regions (element formation regions) 20a partitioned by an element isolation unit 20b. The photoelectric conversion regions 20a are provided for individual pixels 3. Note that the number of pixels 3 is not limited to that in FIG. 4. The photoelectric conversion regions 20a each are provided with a photoelectric conversion unit 21 described later. Furthermore, the photoelectric conversion region 20a is provided with the transistors and the like illustrated in FIG. 3 although not illustrated.

<Photoelectric Conversion Unit>

The photoelectric conversion unit 21 is formed over the entire thickness of the semiconductor layer 20, and is configured as a pn junction type photodiode including a first conductivity-type semiconductor region, and second conductivity-type semiconductor regions facing both front and back surfaces of the semiconductor layer 20. In this example, the first conductivity-type is n-type and the second conductivity-type is p-type, for convenience. The p-type semiconductor regions facing both front and back surfaces of the semiconductor layer 20 also serve as a hole charge accumulation region for suppressing a dark current. The pixels 3 each including the photodiode PD and the pixel transistor Tr are isolated by the element isolation unit 20b. The element isolation unit 20b includes a p-type semiconductor region and is grounded, for example. Although not illustrated in FIG. 4, the transfer transistor TR of FIG. 3 is configured by forming a source region and a drain region of n-type in a p-type semiconductor well region formed on the first surface S1 side of the semiconductor layer 20, and forming a gate electrode on a substrate surface between the source region and the drain region, via a gate insulating film.

<Plasmonic Filter>

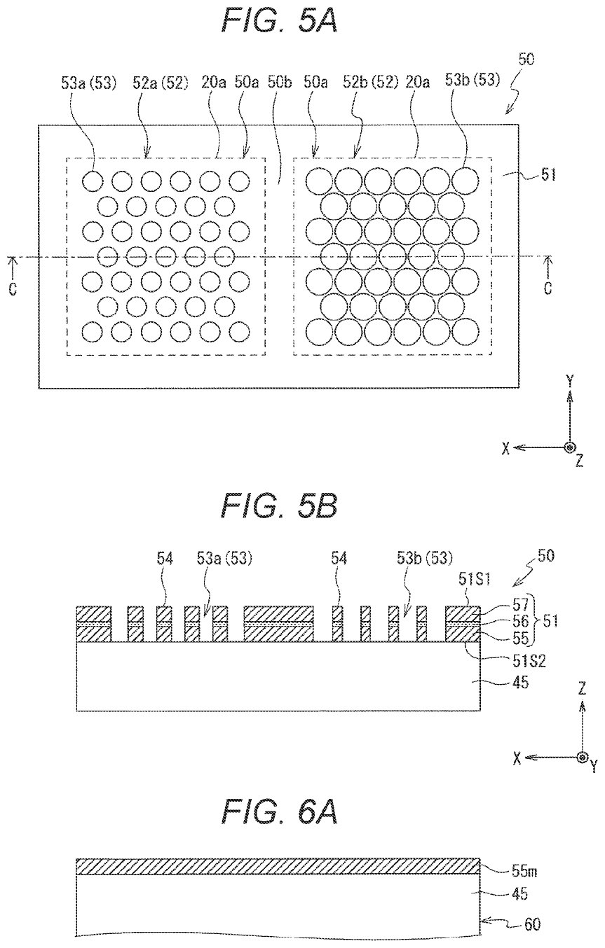

The plasmonic filter 50 illustrated in FIGS. 5A and 5B is a color filter using surface plasmon resonance. The plasmonic filter 50 may work as a plasmon resonance filter that transmits light of a specific wavelength through each through-hole by, for example, forming periodic through-holes arranged at different pitches and/or with different hole diameters for the respective pixels 3, so that a multispectral sensor can be provided. When the plasmonic filter 50 is irradiated with light, energy is excited in the surface layer portion of the plasmonic filter 50, whereby light of a specific wavelength is selected. More specifically, energy is excited in an area of, for example, several tens of nm in the thickness direction from an upper surface 51S1 and a lower surface 51S2 of a base material 51 illustrated in FIG. 5B to the inside of the base material 51, whereby light having a specific wavelength is selected.

Openings 53 to be described later of the plasmonic filter 50 act as waveguides. Generally, a waveguide has a cutoff frequency and a cutoff wavelength determined by its shape such as a side length and a diameter, and has a property of not allowing light having a frequency equal to or lower than the cutoff frequency (wavelength equal to or higher than the cutoff wavelength) to propagate therethrough. The cutoff wavelength of the openings 53 mainly depends on the opening diameter, and the cutoff wavelength becomes longer as the opening diameter is smaller. Note that the opening diameter is set to a value smaller than the wavelength of light to be transmitted. On the other hand, when light is incident on the plasmonic filter 50 in which the through-holes are periodically formed at intervals equal to or less than the wavelength of light, a phenomenon occurs in which light having a wavelength longer than the cutoff wavelength of the through-holes is transmitted. This phenomenon is referred to as an abnormal transmission phenomenon of plasmon.

The plasmonic filter 50 includes the base material 51 and opening arrays 52 formed in the base material 51. That is, the plasmonic filter 50 is an optical element that has the base material 51 and the opening arrays 52 formed in the base material 51, supplies light selected by the opening arrays 52 to the photoelectric conversion unit 21, and is arranged to overlap the photoelectric conversion unit 21 in plan view. The opening arrays 52 each have a plurality of openings 53 arranged at an equal pitch in the base material 51. The openings 53 are holes that penetrate the base material 51 in the thickness direction of the semiconductor layer 20 and have a circular shape in plan view. The opening array 52 has a portion 54 including the base material 51 between two adjacent openings 53. An insulating layer 46 is stacked on a surface of the plasmonic filter 50 opposite to the surface on the insulating layer 45 side. The insulating layer 46 is stacked so as to fill the inside of the openings 53 and cover the base material 51.

The plasmonic filter 50 includes a plurality of types of opening arrays 52 having different diameters and arrangement pitches of the openings 53. FIGS. 5A and 5B illustrate two types of opening arrays (opening arrays 52a, 52b) as an example. The number of types of the opening arrays included in the plasmonic filter 50 is not limited to two, and may be one or three or more. In the example illustrated in FIGS. 5A and 5B, the diameter of openings 53a of the opening array 52a is smaller than the diameter of openings 53b of the opening array 52b. Note that, in a case where it is not necessary to distinguish the types of the opening arrays, the opening arrays 52a and 52b are not distinguished and are simply referred to as the opening arrays 52. As illustrated in FIG. 5A, the plasmonic filter 50 is arranged such that the opening arrays 52 overlap the photoelectric conversion regions 20a (photoelectric conversion unit 21) in plan view. Furthermore, in the region of the plasmonic filter 50 in plan view, regions where the opening arrays 52 are provided are referred to as opening regions 50a, and a region between the adjacent opening regions 50a is referred to as a frame region 50b.

As illustrated in FIG. 5B, the base material 51 has a stacked structure including a first conductor layer 55, an intermediate layer 56, and a second conductor layer 57 sequentially stacked in this order from the semiconductor layer 20 side. The intermediate layer 56 divides the base material 51 into upper and lower parts in the thickness direction. More specifically, the intermediate layer 56 divides the base material 51 into the first conductor layer 55 and the second conductor layer 57 in the thickness direction. Since the base material 51 has such a three-layer structure, the portion 54 of the base material 51 located between the adjacent openings 53 also has a three-layer structure including the first conductor layer 55, the intermediate layer 56, and the second conductor layer 57. The intermediate layer 56 provided between the first conductor layer 55 and the second conductor layer 57 includes an oxide of a material included in the first conductor layer 55. Furthermore, the material included in the intermediate layer 56 is desirably higher in rigidity than the material included in the first conductor layer 55 and the second conductor layer 57.

Each of the first conductor layer 55 and the second conductor layer 57 includes a metal material or an organic conductive film. The metal material is, for example, any metal of aluminum (Al), silver (Ag), gold (Au), copper (Cu), platinum (Pt), molybdenum (Mo), chromium (Cr), titanium (Ti), nickel (Ni), tungsten (W), and iron (Fe), or an alloy containing at least one of those metals. Furthermore, the organic conductive film is, for example, an organic material such as a styrene resin, an acrylic resin, a styrene-acrylic resin, or a siloxane resin. In the plasmonic filter 50, it is desirable that the first conductor layer 55 and the second conductor layer 57 have substantially the same plasmon frequency. Therefore, the first conductor layer 55 and the second conductor layer 57 desirably include the same material. In the first embodiment, an example in which the first conductor layer 55 and the second conductor layer 57 includes aluminum and the intermediate layer 56 includes aluminum oxide (Al₂O₃) will be described.

Here, the Young's modulus of the material included in the intermediate layer 56, which is aluminum oxide, is 360 GPa, and is larger than the Young's modulus 70 MPa of the material included in the first conductor layer 55 and the second conductor layer 57, which is aluminum. In other words, the rigidity of the aluminum oxide included in the intermediate layer 56 is higher than the rigidity of the aluminum included in the first conductor layer 55 and the second conductor layer 57. Therefore, the intermediate layer 56 that is aluminum oxide has an effect of relaxing the stress load on the first conductor layer 55 and the second conductor layer 57 including aluminum.

Furthermore, as illustrated in FIG. 4, the plasmonic filter 50 and the light-shielding metal 44 are desirably grounded so as not to be destroyed by plasma damage due to the accumulated charges during processing. The ground structure may be formed in the pixel array, but with all the conductors electrically connected, the ground structure may be provided in a region outside the effective region.

<On-Chip Lens>

As illustrated in FIG. 4, the on-chip lens 48 condenses the incident light on the photoelectric conversion unit 21 without the incident light blocked by the light-shielding metal 44 between the pixels. The on-chip lens 48 is provided for each pixel 3. The on-chip lens 48 may include an organic material such as a styrene resin, an acrylic resin, a styrene-acrylic resin, and a siloxane resin, for example. Furthermore, the on-chip lens 48 may also include an inorganic material such as silicon nitride (Si₃N₄) or silicon oxynitride (SiON), and can also serve as a passivation film to be described later. Furthermore, titanium oxide particles may be dispersed in the above-described organic material or polyimide resin. Furthermore, a material film 49 having a refractive index different from that of the on-chip lens 48 for preventing reflection can be provided on the surface of the on-chip lens 48.

<Light-Shielding Metal>

The light-shielding metal 44 is arranged in boundary regions between the pixels 3 below the plasmonic filter 50 to shield stray light leaking from adjacent pixels. The light-shielding metal 44 only needs to include a material that shields light, and preferably includes a metal film of, for example, aluminum (Al), tungsten (W), copper (Cu), or the like as a material having a high light shielding property and capable of being accurately processed by microfabrication, for example, etching. In addition, the light-shielding metal 44 may include silver (Ag), gold (Au), platinum (Pt), molybdenum (Mo), chromium (Cr), titanium (Ti), nickel (Ni), iron (Fe), tellurium (Te) and the like, or an alloy including these metals. Furthermore, the light-shielding metal 44 may be formed by stacking a plurality of these materials. In order to enhance adhesion to the underlying insulating layer 43, a barrier metal such as titanium (Ti), tantalum (Ta), tungsten (W), cobalt (Co), molybdenum (Mo), alloys thereof, nitrides thereof, oxides thereof, or carbides thereof may be provided below the light-shielding metal 44. Furthermore, the light-shielding metal 44 may also serve as light shielding of a pixel for determining an optical black level, or may also serve as light shielding for preventing noise to a peripheral circuit region.

<Passivation Film>

The passivation film 47 on the plasmonic filter 50 is provided with, for example, silicon nitride, silicon oxynitride, or the like, and is a protective film that prevents a corrosion phenomenon due to intrusion of moisture or the like. In addition, the passivation film 47 has an effect of filling dangling bond by supplying hydrogen atoms, lowering an interface state, and reducing a surface dark current. The passivation film 47 can also adjust the stress balance by adjusting the film thickness or the like such that the warpage of the substrate is corrected to avoid troubles in conveyance, wafer chuck, and the like.

<Fixed Charge Film>

The fixed charge film 42 has a negative fixed charge due to dipole of oxygen and plays a role of enhancing pinning. The fixed charge film 42 may include, for example, an oxide or nitride including at least one of hafnium (Hf), aluminum (Al), zirconium (Zr), tantalum (Ta), or titanium (Ti). The fixed charge film 42 may be formed by CVD, sputtering, and atomic layer deposition (ALD). In a case where the ALD is adopted, it is possible to simultaneously form a silicon oxide film that reduces the interface state during the deposition of the fixed charge film 42, which is preferable. Furthermore, the fixed charge film 42 may also include an oxide or nitride including at least one of lanthanum, cerium, neodymium, promethium, samarium, europium, gadolinium, terbium, dysprosium, holmium, thulium, ytterbium, lutetium, or yttrium. Furthermore, the fixed charge film 42 may include hafnium oxynitride or aluminum oxynitride. Furthermore, silicon or nitrogen may be added to the fixed charge film 42 in an amount that does not impair an insulating property. Therefore, heat resistance and the like can be improved. The fixed charge film 42 desirably has a function as an antireflection film for a silicon substrate having a high refractive index by controlling the film thickness or stacking multiple layers.

<Wiring Layer>

The wiring layer 30 transmits image signals generated by the pixels 3. Furthermore, the wiring layer 30 further transmits a signal applied to the pixel circuit. Specifically, the wiring layer 30 includes wirings 31 included in the various signal lines and the power supply line Vdd described with reference to FIGS. 2 and 3. The wiring layer 30 and the pixel circuit are connected by via plugs. Furthermore, the wiring layer 30 includes multiple layers, and the wiring layers are also connected by via plugs. The wiring layer 30 may include metal such as Al or Cu, for example. The via plugs can include, for example, a metal such as tungsten or copper. For insulation of the wiring layer 30, for example, a silicon oxide film or the like can be used.

<Support Substrate>

The support substrate 41 is a substrate that reinforces and supports the semiconductor layer 20, the wiring layer 30, and the like in the manufacturing process of the photodetection device 1, and includes, for example, a silicon substrate. The support substrate 41 is bonded to the wiring layer 30 by plasma bonding or an adhesive material, and supports the semiconductor layer 20 and the like. Furthermore, in a case where the photodetection device 1 is a stacked CMOS image sensor (CIS), the support substrate 41 may include, for example, a logic circuit 13 illustrated in FIG. 3 or the like, and formation of connection vias between the semiconductor layer 20 and the support substrate 41 allows vertically stacking of various peripheral circuit functions, so that a chip size can be reduced.

<<Method of Manufacturing Photodetection Device>>

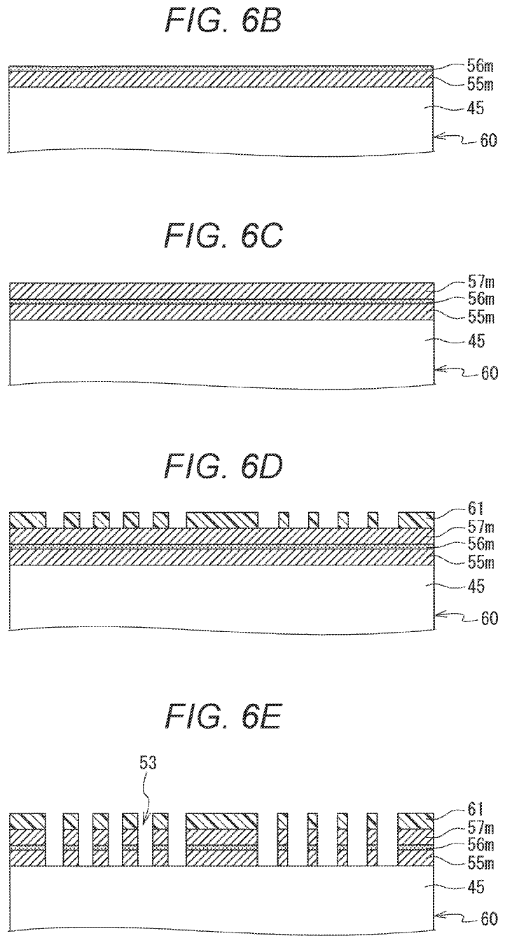

Hereinafter, a method of manufacturing the photodetection device 1 will be described with reference to FIGS. 6A to 6F. First, a substrate 60 is prepared, and as illustrated in FIG. 6A, a film 55m including a material forming the first conductor layer 55 is formed on the insulating layer 45 of the prepared substrate 60 by using a method such as CVD or sputtering. Here, the substrate 60 includes layers from the support substrate 41 to the insulating layer 45. The thickness of the film 55m may be determined considering characteristics of the photodetection device 1, ease of processing, and the like, and is, for example, about 20 nm to 150 nm.

Furthermore, the film 55m is also formed inside the grooves formed in the underlying insulating layer 45 outside the effective region although not illustrated in FIG. 6A. Thus, the film 55m can be electrically connected to the light-shielding metal 44 or the semiconductor layer 20 that is grounded (connected to the reference potential). Electrical connection of the film 55m to the light-shielding metal 44 or the semiconductor layer 20 can suppress plasma damage due to the accumulated charges during processing.

Next, as illustrated in FIG. 6B, a film 56m including a material included in the intermediate layer 56 is formed on the film 55m. More specifically, the film 56m is formed on the surface of the film 55m opposite to the surface on the insulating layer 45 side. The film 56m may be formed by oxidizing the surface of the film 55m opposite to the surface on the insulating layer 45 side. For example, the film 55m may be heated in an oxygen atmosphere, or the film 55m may be irradiated with oxygen plasma to form the film 56m. Furthermore, the film 56m may be formed by stacking aluminum oxide (Al₂O₃) on a surface of the film 55m opposite to the surface on the insulating layer 45 side by CVD or the like. The thickness of the film 56m is, for example, 1 nm or more and 50 nm or less.

Then, as illustrated in FIG. 6C, a film 57m including a material forming the second conductor layer 57 is formed on the film 56m. More specifically, the film 57m is formed on the surface of the film 56m opposite to the surface on the film 55m side. The thickness of the film 57m may be determined considering characteristics of the photodetection device 1, ease of processing, and the like, and is, for example, about 20 nm to 150 nm.

Note that the thicknesses of the film 55m and the film 57m described above may be determined by dividing the dimension obtained by subtracting the thickness of the intermediate layer 56 from the finished thickness of the plasmonic filter 50 into the thicknesses of the film 55m and the film 57m, for example. For example, a dimension obtained by subtracting the thickness of the intermediate layer 56 from the finished thickness of the plasmonic filter 50 may be divided into the thicknesses of the film 55m and the film 57m, for example. More specifically, as an example, a case is considered in which the dimension of the thickness of the finished plasmonic filter 50 is 150 nm and the thickness of the film 56m is 10 nm. In this case, when a thickness of 10 nm of the film 56m is subtracted from 150 nm, the remaining thickness is 140 nm. Then, for example, a half of 140 nm, that is, 70 nm may be allocated to the film 55m, and the remaining half, that is, 70 nm may be allocated to the film 57m.

Next, as illustrated in FIG. 6D, a resist pattern 61 is stacked on the film 57m using a known lithography technique. Then, as illustrated in FIG. 6E, from the film 57m to the film 55m in the exposed portions are removed by dry etching using the resist pattern 61 as a mask. Regions from which the film 57m, the film 56m, and the film 55m are removed become the openings 53. Thereafter, as illustrated in FIG. 6F, the resist pattern 61 and processing residues are removed by chemical cleaning. As a result, the plasmonic filter 50 is formed.

After the plasmonic filter 50 is formed, the insulating layer 46 is formed on the plasmonic filter 50 although not illustrated. The formed insulating layer 46 is also embedded inside the openings 53 of the plasmonic filter 50. The insulating layer 46 is, for example, a silicon oxide film, and is formed by ALD, CVD, sputtering, or the like, but ALD is preferable in view of embeddability. Then, the above-described passivation film 47 includes, for example, silicon nitride on the insulating layer 46 in a thickness of 100 to 500 nm. Therefore, a corrosion phenomenon due to intrusion of moisture or the like can be prevented. Thereafter, the on-chip lens 48 and the like are formed, and the photodetection device 1 illustrated in FIG. 4 is almost completed. The photodetection device 1 is formed in each of a plurality of chip formation regions partitioned by scribe lines (dicing lines) on a semiconductor substrate. Then, the plurality of chip formation regions is separated along the scribe lines into individual chip formation regions, thereby forming the semiconductor chips 2 on each of which the photodetection device 1 is mounted.

<<Main Effects of First Embodiment>>

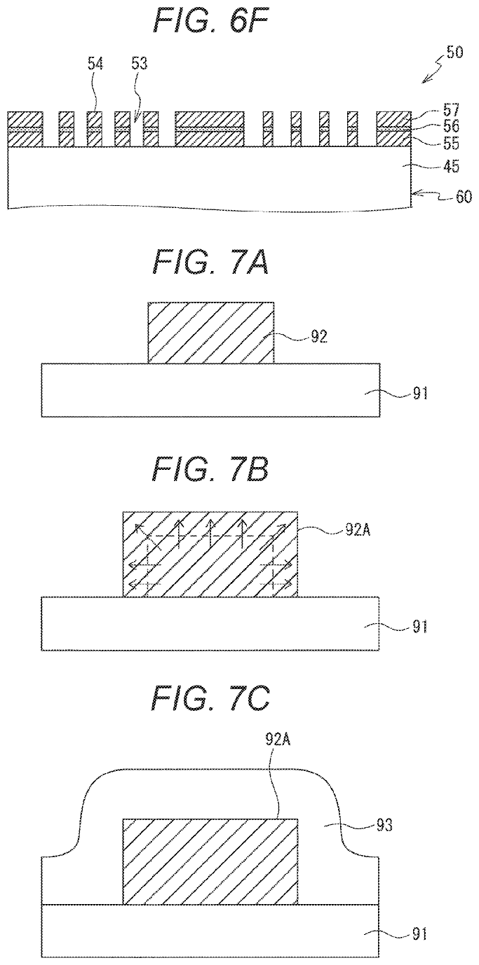

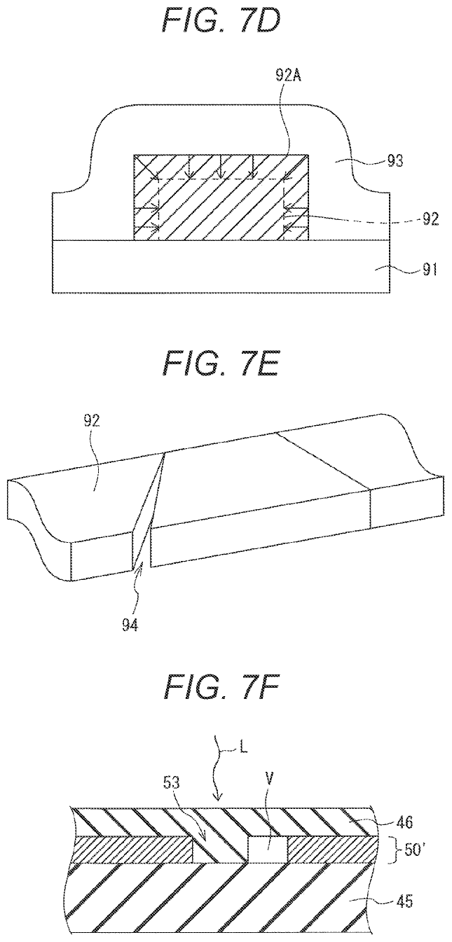

Before describing main effects of the first embodiment, first, stress migration using a general aluminum wiring as an example will be described with reference to FIGS. 7A to 7E. As illustrated in FIG. 7A, an aluminum wiring 92 is provided on an insulating layer 91, and the temperature is then raised from, for example, 300 degrees to about 400 degrees, so that the aluminum wiring 92 is expanded by heat to have a size indicated by the reference sign 92A as illustrated in FIG. 7B. Thereafter, the insulating layer 93 is formed as illustrated in FIG. 7C at the increased temperature, and the temperature is then lowered to room temperature. When the temperature is lowered, a stress to shrink is generated in the aluminum wiring 92A as illustrated in FIG. 7D. This is a phenomenon caused by a difference in linear expansion coefficient between aluminum and silicon oxide included in the insulating layer. From this state, the temperature is raised again to perform a thermal test, atoms of aluminum may be activated by heat and move according to the stress. Then, atoms in the vicinity of the grain boundary of aluminum move, and a void 94 may be generated in the aluminum wiring 92 as illustrated in FIG. 7E.

Although the stress migration is described using the aluminum wiring as an example, the plasmonic filter 50 generally has a film thickness, a minimum dimension, and a minimum pitch smaller than those of the aluminum wiring. Furthermore, a barrier metal may be provided on the surface of the aluminum wiring as a countermeasure against stress migration. However, in the case of the plasmonic filter 50, as described above, energy is excited in a range over, for example, several tens of nm in the thickness direction from the upper surface 51S1 and the lower surface 51S2 of the base material 51 illustrated in FIG. 5B to the inside of the base material 51, so that light having a specific wavelength is selected, and it is not possible to provide a barrier metal on the surface of the plasmonic filter 50. As described above, the plasmonic filter 50 may be more strongly affected by the stress migration than the aluminum wiring.

FIG. 7F illustrates an example of a case where a conventional plasmonic filter 50′ is affected by the stress migration. In the example of FIG. 7F, a void Vis generated in the plasmonic filter 50′ due to the stress migration. The width of the opening 53 is then widened by the void V. In such a state, light L passes through the plasmonic filter 50′ via the portion of the void V.

On the other hand, in the plasmonic filter 50 according to the first embodiment of the present technology, the conductor layer is divided into two layers of the first conductor layer 55 and the second conductor layer 57. In addition, the intermediate layer 56 including a material that is higher in rigidity than the material included in the first conductor layer 55 and the second conductor layer 57 is provided between the separated first conductor layer 55 and second conductor layer 57, so that occurrence of stress migration can be suppressed. Moreover, since the intermediate layer 56 is not exposed to the upper surface 51S1 or the lower surface 51S2 of the base material 51 as illustrated in FIG. 5B, it is possible to suppress the occurrence of stress migration while suppressing the influence on the performance of the plasmonic filter 50. Furthermore, by setting the thickness of the intermediate layer 56 to 50 nm or less, it is possible to suppress the occurrence of stress migration while suppressing the influence on the performance of the plasmonic filter 50.

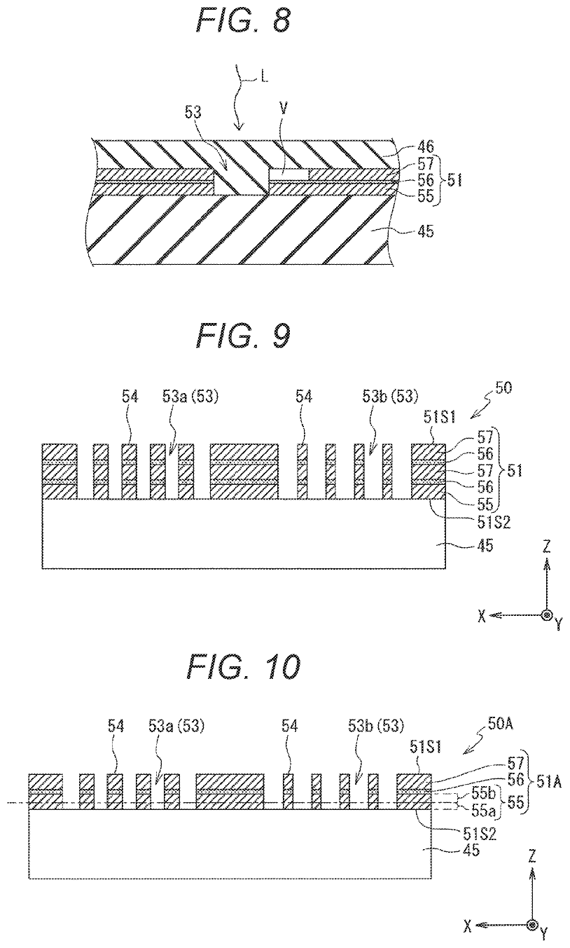

Furthermore, the plasmonic filter 50 according to the first embodiment of the present technology can suppress the influence of a void on the plasmonic filter 50 even in a case where stress migration occurs. In the example illustrated in FIG. 8, the void Vis generated in the second conductor layer 57 of the base material 51. The void V generated in the second conductor layer 57 is prevented from proceeding along the thickness direction of the semiconductor layer 20 by the intermediate layer 56 including a material that is higher in rigidity than the material included in the first conductor layer 55 and the second conductor layer 57. Therefore, the void V does not proceed beyond the intermediate layer 56 in the thickness direction of the semiconductor layer 20. Therefore, generation of the void V in the first conductor layer 55 can be suppressed. As a result, it is possible to suppress passage of the light L through the plasmonic filter 50 via the portion of the void V. Furthermore, the influence of the void V on the function of the plasmonic filter 50 also can be suppressed since the first conductor layer 55 remains.

As described above, by dividing the plasmonic filter 50 vertically in the thickness direction (Z direction) by the intermediate layer 56, the movement of the metal material included in the first conductor layer 55 and the second conductor layer 57 can be limited. For example, even if the movement of the metal material occurs on the first conductor layer 55 side, the movement of the metal material can be limited, and, for example, the movement of the metal material is suppressed on the second conductor layer 57 side. As a result, it is possible to suppress passage of the light L through the plasmonic filter 50 via the portion of the void V.

Note that in the first embodiment, the first conductor layer 55 and the second conductor layer 57 include the same material, but may include different materials. In this case, the material included in the intermediate layer 56 may be an oxide of the material included in the second conductor layer 57. In a case where the material included in the intermediate layer 56 is an oxide of the material included in the second conductor layer 57, the film 56m is formed by stacking by CVD or the like on the surface of the film 55m opposite to the surface on the insulating layer 45 side.

Moreover, the intermediate layer 56 may include any high melting point metal having a higher melting point and higher rigidity than the first conductor layer 55 and the second conductor layer 57, a nitride of the high melting point metal, an oxide of the high melting point metal, a carbide of the high melting point metal, an alloy including the high melting point metal, a nitride of the alloy, an oxide of the alloy, and a carbide of the alloy. In addition, the high melting point metal may be, for example, any of titanium (Ti), tantalum (Ta), tungsten (W), cobalt (Co), molybdenum (Mo), and hafnium (Hf). Furthermore, the thickness of the intermediate layer 56, which is a high melting point metal, is 1 nm or more and 50 nm or less, for example. The thickness of the intermediate layer 56 is more preferably 10 nm or less.

Furthermore, in the first embodiment, one intermediate layer 56 is provided, but a plurality of the Intermediate layers may be provided. FIG. 9 illustrates an example in which two intermediate layers 56 are provided. The base material 51 includes the first conductor layer 55, the intermediate layer 56, the second conductor layer 57, the intermediate layer 56, and the second conductor layer 57 sequentially stacked this order from the semiconductor layer 20 side. By providing a plurality of intermediate layers 56, the rigidity of the base material 51 can be further enhanced. Moreover, since the plasmonic filter 50 can be divided into more regions in the thickness direction (Z direction), even in a case where stress migration occurs, the influence thereof can be further suppressed.

[Modification 1 of First Embodiment]

Modification 1 of the first embodiment of the present technology illustrated in FIG. 10 will be described below. A photodetection device 1 according to Modification 1 of the first embodiment is different from the photodetection device 1 according to the first embodiment described above in that a material included in an intermediate layer 56 is diffused in a part of a first conductor layer 55, and other than that point, the configuration of the photodetection device 1 is basically similar to that of the photodetection device 1 according to the first embodiment described above. Note that the components already described will be denoted by the same reference signs, and the description thereof will be omitted.

<Plasmonic Filter>

A plasmonic filter 50A includes a base material 51A and opening arrays 52 formed in the base material 51A. Then, the opening arrays 52 each have a plurality of openings 53 arranged at an equal pitch in the base material 51A. The base material 51A includes a first conductor layer 55, an intermediate layer 56, and a second conductor layer 57. The intermediate layer 56 includes any of high melting point metal that is higher in melting point and higher in rigidity than a first conductor layer 55 and a second conductor layer 57, a nitride of the high melting point metal, an oxide of the high melting point metal, a carbide of the high melting point metal, an alloy including the high melting point metal, a nitride of the alloy, an oxide of the alloy, and a carbide of the alloy. Then, the material included in the intermediate layer 56 is diffused into a part of the first conductor layer 55. Here, the intermediate layer 56 will be described as including titanium, which is a high melting point metal.

Since the first conductor layer 55 and the intermediate layer 56 are sequentially stacked along the thickness direction of the semiconductor layer 20, titanium atoms are diffused from the intermediate layer 56 to the first conductor layer 55 beyond the boundary between the first conductor layer 55 and the intermediate layer 56. Titanium atoms are diffused into a part of the first conductor layer 55, and the first conductor layer 55 also has a region where titanium atoms are not diffused. Here, in the first conductor layer 55, a region where titanium atoms are not diffused is referred to as a first portion 55a, and a region where titanium atoms are diffused is referred to as a second portion 55b. The first portion 55a is a portion of at least 50 nm in the thickness direction from a surface (lower surface 51S2) of the first conductor layer 55 opposite to the intermediate layer 56 side. In addition, the second portion 55b is in contact with the intermediate layer 56.

For example, when titanium atoms are diffused into the first conductor layer 55 including aluminum, the rigidity of the first conductor layer 55 is increased, and the first conductor layer becomes stronger against stress migration. However, when titanium atoms are diffused throughout the first conductor layer 55, titanium atoms exist up to the lower surface 51S2. In such a state, titanium atoms may affect the surface plasmons. As described above, when the plasmonic filter 50A is irradiated with light, energy is excited in the surface layer portion of the plasmonic filter 50A, more specifically, in ranges of several tens of nm in depth from an upper surface 51S1 and the lower surface 51S2. Therefore, it is desirable that the region where the energy is excited does not contain a substance that may affect the energy excitation.

<<Method of Manufacturing Photodetection Device>>

Hereinafter, a method of manufacturing the photodetection device 1 will be described. Here, differences from the method of manufacturing the photodetection device 1 described in the first embodiment will be described. First, a film 55m, and a film 56m including titanium are sequentially formed by performing steps similar to the steps illustrated in FIGS. 6A and 6B. Thereafter, before the step illustrated in FIG. 6C is performed, heat treatment is performed to diffuse the material included in the intermediate layer 56 into a part (second portion 55b) of the first conductor layer 55. Then, the remaining steps illustrated in FIGS. 6C to 6F are performed.

<<Main Effects of Modification 1 of First Embodiment>>

Even in the photodetection device 1 according to Modification 1 of the first embodiment, effects similar to those of the photodetection device 1 according to the first embodiment described above can be obtained.

Furthermore, in Modification 1 of the first embodiment, the material included in the intermediate layer 56 is diffused in the second portion 55b of the first conductor layer 55, so that rigidity of the first conductor layer 55 is increased, and occurrence of stress migration can be further suppressed.

Moreover, since the material included in the intermediate layer 56 is not diffused in the first portion 55a of the first conductor layer 55, the occurrence of stress migration can be further suppressed while suppressing the influence on the performance of the plasmonic filter 50.

[Modification 2 of First Embodiment]

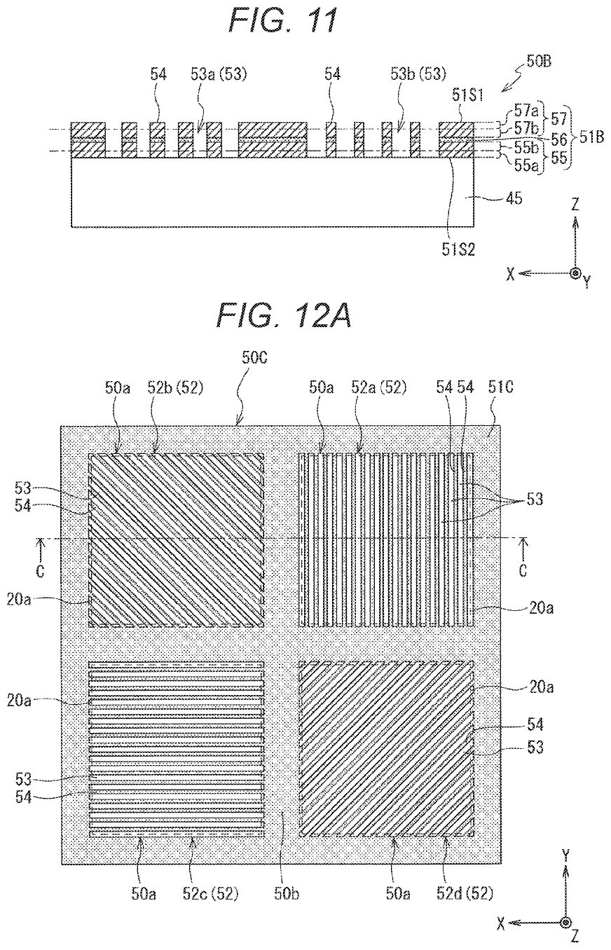

Modification 2 of the first embodiment of the present technology illustrated in FIG. 11 will be described below. A photodetection device 1 according to Modification 2 of the first embodiment is different from the photodetection devices 1 according to the first embodiment and Modification 1 of the first embodiment described above in that a material included in an intermediate layer 56 is diffused in a part of a first conductor layer 55 and also in a part of a second conductor layer 57, and other than that point, the configuration of the photodetection device 1 is basically similar to those of the photodetection device 1 according to the first embodiment and Modification 1 of the first embodiment described above. Note that the components already described will be denoted by the same reference signs, and the description thereof will be omitted.

<Plasmonic Filter>

A plasmonic filter 50B includes a base material 51B and the opening arrays 52 formed in the base material 51B. Then, the opening arrays 52 each have the plurality of openings 53 arranged at an equal pitch in the base material 51B. The base material 51B includes a first conductor layer 55, an intermediate layer 56, and a second conductor layer 57. The intermediate layer 56 includes the material described in Modification 1 of the first embodiment. Here, the intermediate layer 56 will be described as including titanium, which is a high melting point metal.

Since the intermediate layer 56 and the second conductor layer 57 are sequentially stacked along the thickness direction of the semiconductor layer 20, titanium atoms are diffused from the intermediate layer 56 to the second conductor layer 57 beyond the boundary between the second conductor layer 57 and the intermediate layer 56. Here, in the second conductor layer 57, a region where titanium atoms are not diffused is referred to as a first portion 57a, and a region where titanium atoms are diffused is referred to as a second portion 57b. The first portion 57a is a portion of at least 50 nm in the thickness direction from a surface (upper surface 51S1) of the second conductor layer 57 opposite to the intermediate layer 56 side. In addition, the second portion 57b is in contact with the intermediate layer 56.

<<Method of Manufacturing Photodetection Device>>

Hereinafter, a method of manufacturing the photodetection device 1 will be described. Here, differences from the method of manufacturing the photodetection device 1 described in the first embodiment will be described. First, a film 55m, a film 56m including titanium, and a film 57m are sequentially formed by performing steps similar to the steps illustrated in FIGS. 6A to 6C. Thereafter, before performing the step illustrated in FIG. 6D, heat treatment is performed to diffuse the material included in the intermediate layer 56 into a part of the first conductor layer 55 and a part (second portion 57b) of the second conductor layer 57. Then, the remaining steps illustrated in FIGS. 6D to 6F are performed.

<<Main Effects of Modification 2 of First Embodiment>>

Even in the photodetection device 1 according to Modification 2 of the first embodiment, effects similar to those of the photodetection device 1 according to the first embodiment and Modification 1 of the first embodiment described above can be obtained.

Furthermore, in Modification 2 of the first embodiment, the material included in the intermediate layer 56 is diffused in both the first conductor layer 55 and the second conductor layer 57, so that rigidity of both the first conductor layer 55 and the second conductor layer 57 is increased, and occurrence of stress migration can be further suppressed as compared with the case of Modification 1 of the first embodiment.

Moreover, since the material included in the intermediate layer 56 is not diffused in the first portion 55a of the first conductor layer 55 or the first portion 57a of the second conductor layer 57, the occurrence of stress migration can be further suppressed while suppressing the influence on the performance of the plasmonic filter 50.

### SECOND EMBODIMENT

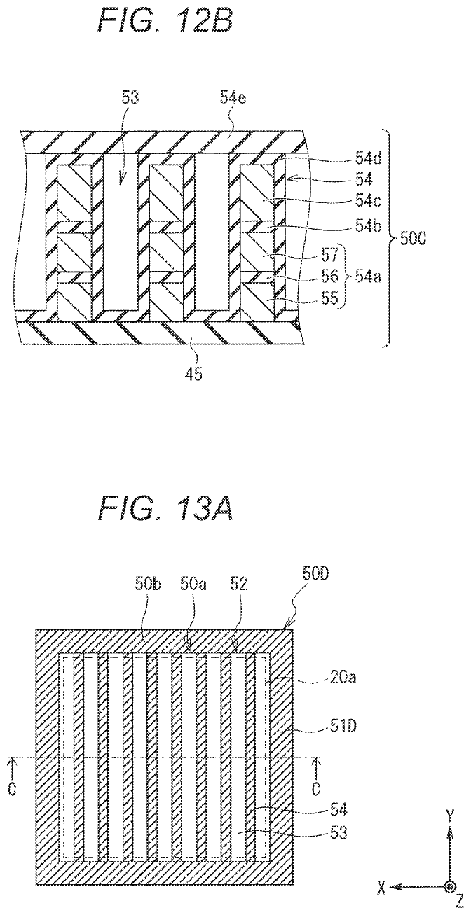

A second embodiment of the present technology illustrated in FIGS. 12A and 12B will be described below. A photodetection device 1 according to the second embodiment is different from the photodetection device 1 according to the first embodiment described above in that the photodetection device 1 includes, instead of a plasmonic filter, a wire grid polarizer 50C as an optical element including a conductor layer, and other than that point, the configuration of the photodetection device 1 is basically similar to that of the photodetection device 1 according to the first embodiment described above. Note that the components already described will be denoted by the same reference signs, and the description thereof will be omitted.

<Wire Grid Polarizer>

As illustrated in FIG. 12A, the wire grid polarizer 50C is an optical element that has a base material 51C and opening arrays 52 formed in the base material 51C, supplies light selected by the opening arrays 52 to photoelectric conversion regions 20a, and is arranged to overlap a photoelectric conversion unit 21 in plan view. More specifically, the wire grid polarizer 50C is an optical element that selects light having a specific polarization plane according to the arrangement direction of openings 53 to be described later of the opening arrays 52 and supplies the selected light to the photoelectric conversion region 20a (photoelectric conversion unit 21). Furthermore, the wire grid polarizer 50C is arranged to overlap the photoelectric conversion region 20a in plan view. More specifically, the wire grid polarizer 50C is arranged such that the opening arrays 52 overlap the photoelectric conversion regions 20a in plan view. In the region of the wire grid polarizer 50C in plan view, regions where the opening arrays 52 are provided are referred to as opening regions 50a, and a region between the opening regions 50a is referred to as a frame region 50b.

The base material 51C includes a material included in a light reflecting layer 54a, a material included in an insulating layer 54b, and a material included in a light absorbing layer 54c to be described later. The light reflecting layer 54a includes a material included in a first conductor layer 55, a material included in an intermediate layer 56, and a material included in a second conductor layer 57 sequentially stacked in this order from the semiconductor layer 20 side.

The opening arrays 52 each have a plurality of openings 53 arranged at an equal pitch in the base material 51C. The openings 53 are grooves that penetrate the base material 51C in the thickness direction of a semiconductor layer 20. In addition, the opening array 52 has a portion (in the second embodiment of the present technology, the portion is referred to as a strip-shaped conductor) 54 including the base material 51C between adjacent two of the openings 53. In other words, the opening array 52 forms a plurality of strip-shaped conductors 54 arranged at an equal pitch.

The wire grid polarizer 50C has the opening arrays 52 of a plurality of types having different arrangement directions of the openings 53 (strip-shaped conductors 54). FIG. 12A illustrates an example in which, for example, the wire grid polarizer 50C includes the opening arrays 52 of four types (opening arrays 52a, 52b, 52c, and 52d). The arrangement direction of the openings 53 (strip-shaped conductors 54) of the opening array 52a is a direction along the X direction. The arrangement direction of the openings 53 (strip-shaped conductors 54) of the opening array 52b is a direction along a direction of 45 degrees with respect to the X direction. The arrangement direction of the openings 53 (strip-shaped conductors 54) of the opening array 52c is a direction along a direction of 90 degrees with respect to the X direction. The arrangement direction of the openings 53 (strip-shaped conductors 54) of the opening array 52d is a direction along a direction of 135 degrees with respect to the X direction. Note that in a case where it is not necessary to distinguish the arrangement direction of the openings 53 (strip-shaped conductors 54), the opening arrays 52a, 52b, 52c, and 52d are not distinguished and are simply referred to as opening arrays 52.

Furthermore, as illustrated in FIG. 12B, the strip-shaped conductors 54 each are formed by stacking a light reflecting layer 54a, an insulating layer 54b, and a light absorbing layer 54c in this order. The light reflecting layer 54a is stacked on an insulating layer 45. Moreover, the strip-shaped conductor 54 has a protective layer 54d on the outer periphery of the light reflecting layer 54a, insulating layer 54b, and light absorbing layer 54c that are stacked.

The light reflecting layer 54a reflects incident light. The light reflecting layer 54a includes the first conductor layer 55, the intermediate layer 56 and the second conductor layer 57 sequentially stacked in this order from the semiconductor layer 20 side. The configuration of the first conductor layer 55, the intermediate layer 56, and the second conductor layer 57, and the materials included in the first conductor layer 55, the intermediate layer 56, and the second conductor layer 57 are as described in the first embodiment described above. The film thicknesses of the first conductor layer 55, the intermediate layer 56, and the second conductor layer 57 may be the same as those described in the first embodiment. Here, the first conductor layer 55 is formed to have a thickness of 70 nm, the intermediate layer 56 is formed to have a thickness of 10 nm, and the second conductor layer 57 is formed to have a thickness of 70 nm.

The light absorbing layer 54c absorbs incident light. Examples of the material forming the light absorbing layer 54c may include a metal material and an alloy material having an extinction coefficient k of not 0, that is, having a light absorbing action, specifically, metal materials such as aluminum (Al), silver (Ag), gold (Au), copper (Cu), molybdenum (Mo), chromium (Cr), titanium (Ti), nickel (Ni), tungsten (W), iron (Fe), silicon (Si), germanium (Ge), tellurium (Te), and tin (Sn), and alloy materials including these metals. Furthermore, silicide-based materials such as FeSi2 (especially β-FeSi2), MgSi2, NiSi2, BaSi2, CrSi2, and CoSi2 may also be exemplified. In particular, by using aluminum or an alloy thereof, or a semiconductor material including β-FeSi2, germanium, or tellurium as a material included in the light absorbing layer 54c, high contrast (appropriate extinction ratio) can be obtained in the visible light region. Note that silver (Ag), copper (Cu), gold (Au) and the like is preferably used as a material included in the light absorbing layer 54c in order to impart a polarization characteristic to a wavelength band other than visible light, for example, an infrared region. This is because resonance wavelengths of these metals are in the vicinity of the infrared region.

The insulating layer 54b is, for example, an insulator including a silicon oxide film. The insulating layer 54b is arranged between the light reflecting layer 54a and the light absorbing layer 54c.

The protective layer 54d protects the light reflecting layer 54a, the insulating layer 54b, and the light absorbing layer 54c stacked in this order. The protective layer 54d may include, for example, a silicon oxide film.

Furthermore, the wire grid polarizer 50C includes a planarization film 54e stacked on the end side of the strip-shaped conductor 54 opposite to the end on the insulating layer 45 side. The planarization film 54e can include, for example, a silicon oxide film.

<<Main Effects of Second Embodiment>>

Even in the photodetection device 1 according to the second embodiment, effects similar to those of the photodetection device 1 according to the first embodiment described above can be obtained.

Note that in the second embodiment, the strip-shaped conductor 54 includes the light reflecting layer 54a, the insulating layer 54b, the light absorbing layer 54c, and the protective layer 54d. However, the strip-shaped conductor 54 is not limited thereto as long as the strip-shaped conductor 54 includes at least the light reflecting layer 54a. Furthermore, the wire grid polarizer 50C has an air-gap structure, but may have another structure. For example, an insulating film may be embedded in the openings 53.

### THIRD EMBODIMENT

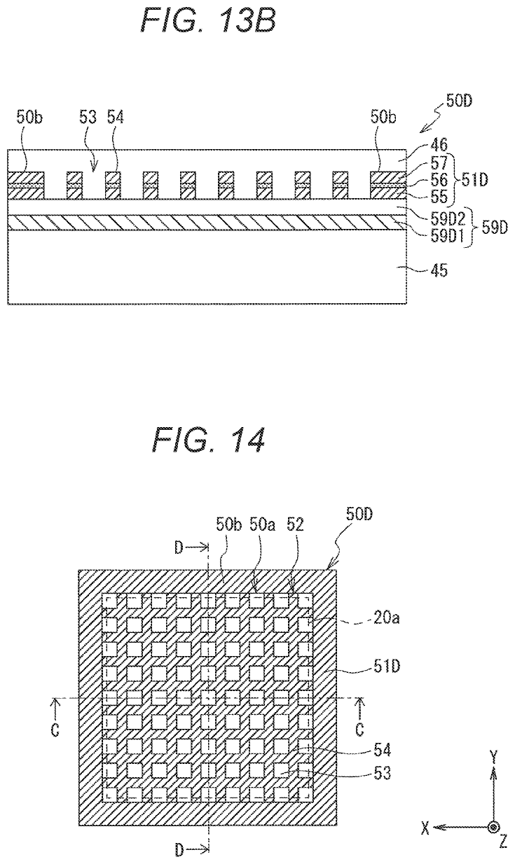

A third embodiment of the present technology illustrated in FIGS. 13A and 13B will be described below. A photodetection device 1 according to the third embodiment is different from the photodetection device 1 according to the first embodiment described above in that the photodetection device 1 includes, instead of a plasmonic filter, a guided mode resonance (GMR) color filter 50D as an optical element including a conductor layer, and other than that point, the configuration of the photodetection device 1 is basically similar to that of the photodetection device 1 according to the first embodiment described above. Note that the components already described will be denoted by the same reference signs, and the description thereof will be omitted.

<GMR Color Filter>

The photodetection device 1 includes a GMR color filter 50D as an optical element. The GMR color filter 50D includes a base material 51D illustrated in FIG. 13A, an opening array (hereinafter, referred to as a diffraction grating in the third embodiment) 52 formed in the base material 51D, and a waveguide 59D illustrated in FIG. 13B, and is an optical element arranged so as to overlap a photoelectric conversion unit 21 in plan view. The GMR color filter 50D supplies light selected by the diffraction grating 52 and the waveguide 59D to the photoelectric conversion unit 21.

The diffraction grating 52 includes a plurality of openings 53 arranged at an equal pitch in the base material 51D and a portion 54 located between the adjacent openings 53 in the base material 51D. The openings 53 are grooves that penetrate the base material 51D in the thickness direction of a semiconductor layer 20. The waveguide 59D is provided between the base material 51D and the insulating layer 45, and has one surface in contact with the base material 51D and the other surface in contact with the insulating layer 45. The waveguide 59D includes a core layer 59D1 and a cladding layer 59D2.

Furthermore, as illustrated in FIG. 13A, in the region of the GMR color filter 50D in plan view, regions where the diffraction gratings 52 are provided are referred to as opening regions 50a, and a region between the adjacent opening regions 50a is referred to as a frame region 50b.

As illustrated in FIG. 13B, the base material 51D includes a first conductor layer 55, an intermediate layer 56, and a second conductor layer 57 sequentially stacked in this order from the semiconductor layer 20 side. The configuration of the first conductor layer 55, the intermediate layer 56, and the second conductor layer 57, and the materials included in the first conductor layer 55, the intermediate layer 56, and the second conductor layer 57 are as described in the first embodiment described above. The portion 54 located between the adjacent openings 53 in the base material 51D also has the same configuration.

<<Main Effects of Third Embodiment>>

Even in the photodetection device 1 according to the third embodiment, effects similar to those of the photodetection device 1 according to the first embodiment described above can be obtained.

Note that the diffraction gratings 52 of the GMR color filter 50D may have a grating shape as illustrated in FIG. 14. In this case, a cross-sectional view taken along line D-D in FIG. 14 has a configuration similar to that in FIG. 13B.

### FOURTH EMBODIMENT

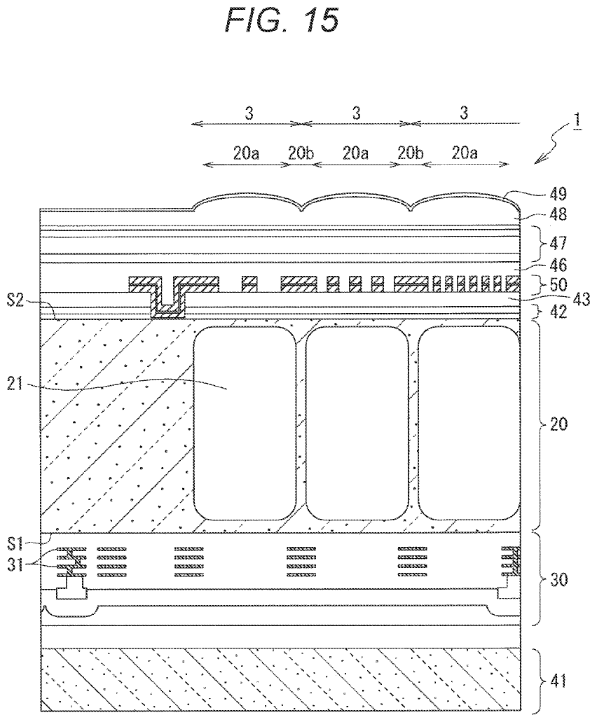

A fourth embodiment of the present technology illustrated in FIG. 15 will be described below. A photodetection device 1 according to the fourth embodiment is different from the photodetection device 1 according to the first embodiment described above in that the photodetection device 1 does not include a light-shielding metal 44 of the first embodiment and a plasmonic filter 50 also serves as a light-shielding metal 44, and other than that point, the configuration of the photodetection device 1 is basically similar to that of the photodetection device 1 according to the first embodiment described above. Note that the components already described will be denoted by the same reference signs, and the description thereof will be omitted.

<Plasmonic Filter>

A plasmonic filter 50 is stacked on a surface of an insulating layer 43 opposite to a semiconductor layer 20 side. Since the plasmonic filter 50 has a light shielding property, it can also serve as a light-shielding metal.

<<Main Effects of Fourth Embodiment>

Even in the photodetection device 1 according to the fourth embodiment, effects similar to those of the photodetection device 1 according to the first embodiment described above can be obtained.

In addition, in the photodetection device 1 according to the fourth embodiment, the processing steps of the light-shielding metal is reduced to reduce the manufacturing cost, and furthermore, the height of the entire light condensing structure is reduced, so that the oblique incidence characteristics are improved. Furthermore, by setting the frame-shaped non-opening region to be wide at the pixel boundaries, it is possible to suppress the crosstalk of the light transmitted through the plasmonic filter 50.

Furthermore, the plasmonic filter 50 according to the fourth embodiment may also serve as a light shielding of a pixel for determining an optical black level, or may also serve as a light shielding for preventing noise to a peripheral circuit region. A preferable film thickness of the plasmonic filter 50 may be determined in consideration of the light shielding performance and the characteristics of the plasmonic filter 50 required for above-described functions.

Note that, the plasmonic filter 50 is desirably grounded (connected to the reference potential) so as not to be destroyed by plasma damage due to the accumulated charges during processing.

### FIFTH EMBODIMENT

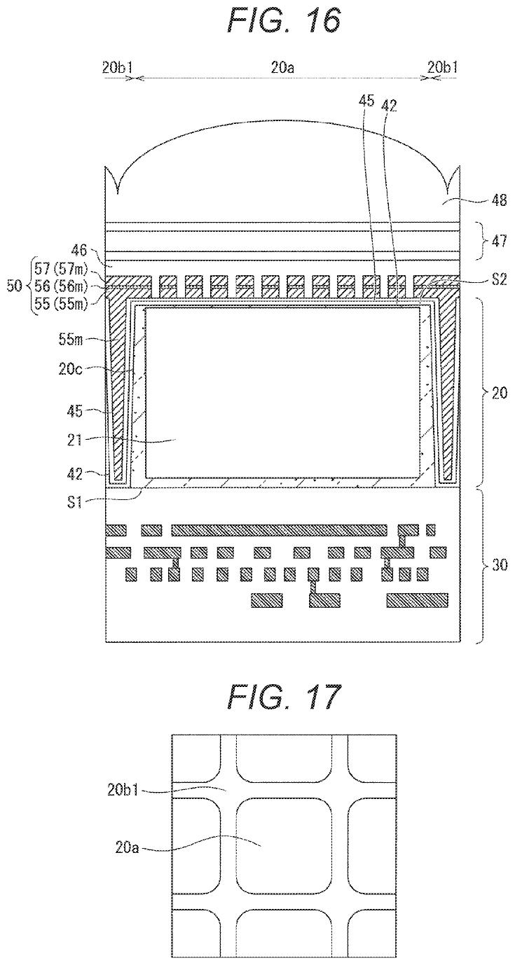

A fifth embodiment of the present technology illustrated in FIGS. 16 and 17 will be described below. A photodetection device 1 according to the fifth embodiment is different from the photodetection device 1 according to the first embodiment described above in that an element isolation unit 20b1 is trench isolation and that the element isolation unit 20b1 includes a material included in a first conductor layer 55, and other than that point, the configuration of the photodetection device 1 is basically similar to that of the photodetection device 1 according to the first embodiment described above. Note that the components already described will be denoted by the same reference signs, and the description thereof will be omitted.

<Element Isolation Unit>

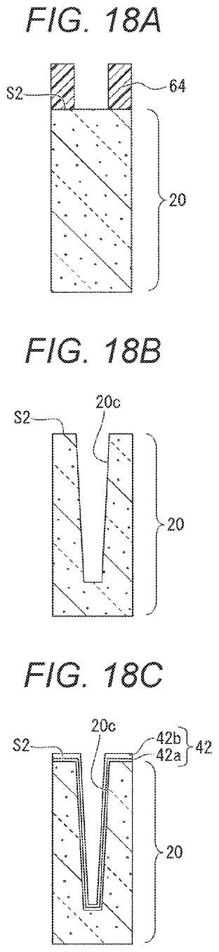

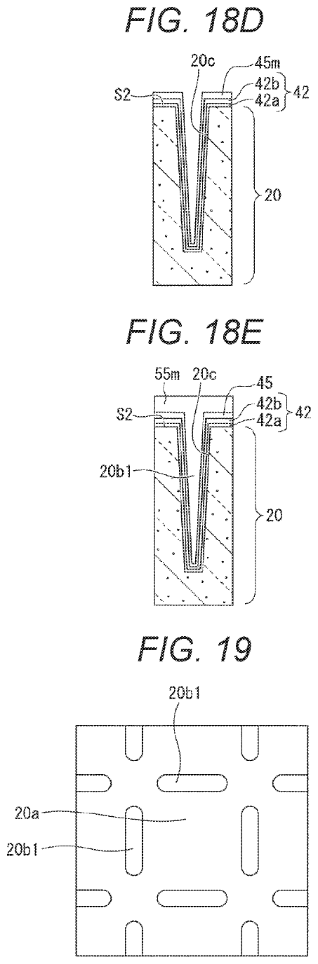

As illustrated in FIG. 16, a semiconductor layer 20 has island-shaped photoelectric conversion regions (element formation regions) 20a partitioned by an element isolation unit 20b1. The element isolation unit 20b1 includes a film 55m embedded in a groove 20c formed in the semiconductor layer 20. The film 55m is a material included in the first conductor layer 55. The groove 20c is formed in the semiconductor layer 20 between the adjacent photoelectric conversion regions 20a (photoelectric conversion units 21). The groove 20c is recessed from the second surface S2 along the thickness direction of the semiconductor layer 20. In addition, the fixed charge film 42 is interposed between the groove 20c and the element isolation unit 20b1. As illustrated in FIG. 18E, the fixed charge film 42 includes a fixed charge film 42a including, for example, aluminum oxide (Al₂O₃) and a fixed charge film 42b including, for example, tantalum oxide (Ta₂O₅). Such a configuration of the fixed charge film 42 is preferable from the viewpoint of dark time characteristics.

Furthermore, as illustrated in FIG. 17, the element isolation unit 20b is provided in a grating shape in plan view, and surround the photoelectric conversion regions 20a (photoelectric conversion units 21).

<<Method of Manufacturing Photodetection Device>>

Hereinafter, a method of manufacturing the photodetection device 1, more specifically, a method of manufacturing the element isolation unit 20b1 will be described with reference to FIGS. 18A to 18E. First, as illustrated in FIG. 18A, a resist pattern 64 is formed on the second surface S2 of the semiconductor layer 20 by exposure and development according to a known lithography technique. Next, as illustrated in FIG. 18B, a trench is dug into the semiconductor layer 20 to a desired depth by a known etching method such as the Bosch process to form the groove 20c. Thereafter, the resist pattern 64 and processing residues are removed by wet cleaning or the like.

Next, as illustrated in FIG. 18C, the fixed charge film 42a and the fixed charge film 42b are stacked in this order in the groove 20c. The fixed charge films 42a and 42b are formed by a known method such as ALD, CVD, or sputtering. Thereafter, as illustrated in FIG. 18D, for example, a silicon oxide film is formed as the insulating layer 45 (45m) by a known method such as ALD, CVD, or sputtering. It is desirable to control the trench width, the method of film formation, and the film thickness so as not to block the upper opening of the groove 20c.

Then, the film 55m is formed as illustrated in FIG. 18E. The film 55m can be formed on the basis of a known method such as various chemical vapor deposition methods (CVD methods), coating methods, various physical vapor deposition methods (PVD methods) including a sputtering method and a vacuum vapor deposition method, a sol-gel method, a plating method, an MOCVD method, an MBE method, and a reflow method. A portion of the film 55m embedded in the groove 20c is the element isolation unit 20b1. In addition, the other portion of the film 55m is used as the film 55m illustrated in FIG. 6A of the first embodiment.

<<Main Effects of Fifth Embodiment>>

Even in the photodetection device 1 according to the fifth embodiment, effects similar to those of the photodetection device 1 according to the first embodiment described above can be obtained.

Furthermore, in the photodetection device 1 according to the fifth embodiment, since the element isolation unit 20b1 is trench isolated, it is possible to suppress the inflow of charges from the adjacent pixels 3, and it is also possible to suppress the incidence of light obliquely incident from the adjacent pixels 3. As a result, it is possible to suppress mixing of noise into the image signal in the pixels 3.

Note that the shape of the element isolation unit 20b1 in plan view is not limited to the grating shape illustrated in FIG. 17, and may be a shape in which the element isolation units 20b1 are partially formed as illustrated in FIG. 19. Alternatively, the element isolation units 20b1 may be designed in a dot pattern or a broken line pattern (not illustrated).

Furthermore, the depth of the element isolation unit 20b1 is preferably as deep as possible from the viewpoint of suppressing crosstalk, and ideally, it is desirable to make the element isolation unit 20b1 penetrate. With respect to the depth, a preferable condition may be applied in comparison with product specifications in consideration of dark time characteristics, processing time, pixel transistor design, potential design by implantation, and the like.

[Modification 1 of Fifth Embodiment]

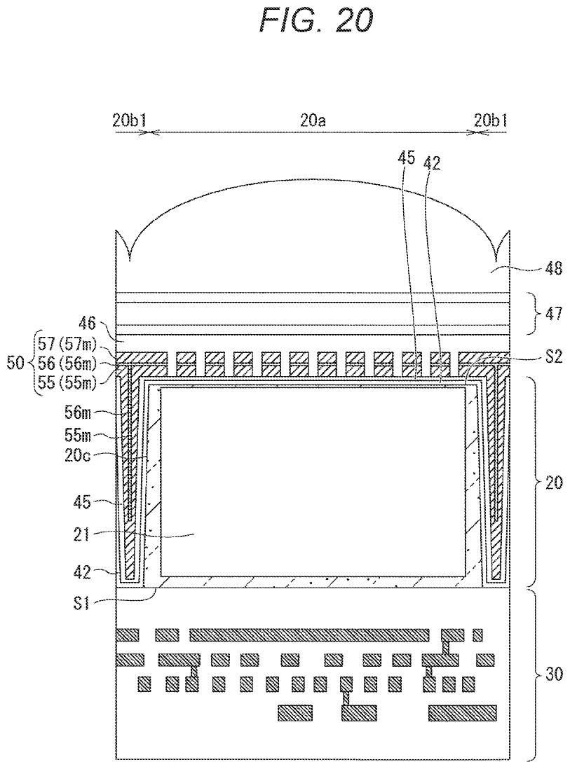

Modification 1 of the fifth embodiment of the present technology illustrated in FIG. 20 will be described below. A photodetection device 1 according to Modification 1 of the fifth embodiment is different from the photodetection device 1 according to the fifth embodiment described above in that an element isolation unit 20b1 includes a material included in a first conductor layer 55 and a material included in an intermediate layer 56, and other than that point, the configuration of the photodetection device 1 is basically similar to that of the photodetection device 1 according to the fifth embodiment described above. Note that the components already described will be denoted by the same reference signs, and the description thereof will be omitted.

<Element Isolation Unit>

The element isolation unit 20b1 includes a film 55m included in the first conductor layer 55 and a film 56m included in the intermediate layer 56. The film 56m can be further formed in the groove 20c by preventing the film 55m from being completely embedded in the groove 20c when the film 55m is embedded in the groove 20c. The film 56m included in the intermediate layer 56 is as described in the first embodiment described above.

<<Main Effects of Modification 1 of Fifth Embodiment>

Even in the photodetection device 1 according to Modification 1 of the fifth embodiment, effects similar to those of the photodetection device 1 according to the fifth embodiment described above can be obtained.

In addition, in the photodetection device 1 according to Modification 1 of the fifth embodiment, since the film 55m and the film 56m are embedded in the groove 20c, the rigidity of the element isolation unit 20b1 is increased, and stress migration can be suppressed. Furthermore, depending on the type of the high melting point metal included in the film 56m, the light shielding property of the element isolation unit 20b1 can be enhanced, and the crosstalk suppression effect can be enhanced.

[Modification 2 of Fifth Embodiment]

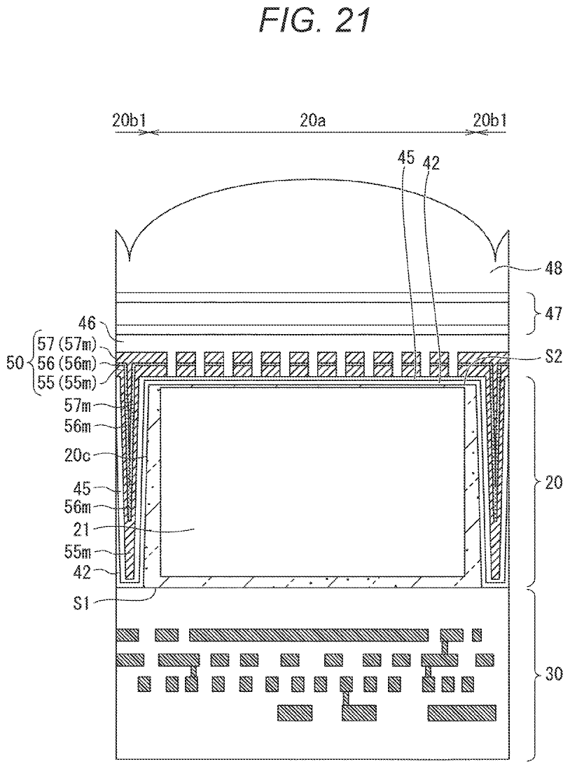

Modification 2 of the fifth embodiment of the present technology illustrated in FIG. 21 will be described below. A photodetection device 1 according to Modification 2 of the fifth embodiment is different from the photodetection device 1 according to the fifth embodiment described above in that an element isolation unit 20b1 includes a material included in a first conductor layer 55, a material included in an intermediate layer 56, and a material included in a second conductor layer 57, and other than that point, the configuration of the photodetection device 1 is basically similar to that of the photodetection device 1 according to the fifth embodiment described above. Note that the components already described will be denoted by the same reference signs, and the description thereof will be omitted.

<Element Isolation Unit>

The element isolation unit 20b1 includes a film 55m included in the first conductor layer 55, a film 56m included in the intermediate layer 56, and a film 57m included in the second conductor layer 57. The film 56m can be formed in the groove 20c by preventing the film 55m from being completely embedded in the groove 20c when the film 55m is embedded in the groove 20c. Then, the film 57m can be further formed in the groove 20c by preventing the film 56m from being completely embedded in the groove 20c when the film 56m is formed in the groove 20c. Since the film 57m is embedded in the groove 20c, the film 56m included in the intermediate layer 56 is formed on both sides in the groove 20c via the film 57m. Here, the film 56m included in the intermediate layer 56 is as described in the first embodiment described above.

<<Main Effects of Modification 2 of Fifth Embodiment>>

Even in the photodetection device 1 according to Modification 2 of the fifth embodiment, effects similar to those of the photodetection device 1 according to the fifth embodiment described above can be obtained.

In addition, in the photodetection device 1 according to Modification 2 of the fifth embodiment, since the film 56m included in the intermediate layer 56 is formed on both sides in the groove 20c via the film 57m, it is possible to enhance the effects of the rigidity enhancement inside the element isolation unit 20b1 or enhancement of the light shielding property.

### SIXTH EMBODIMENT

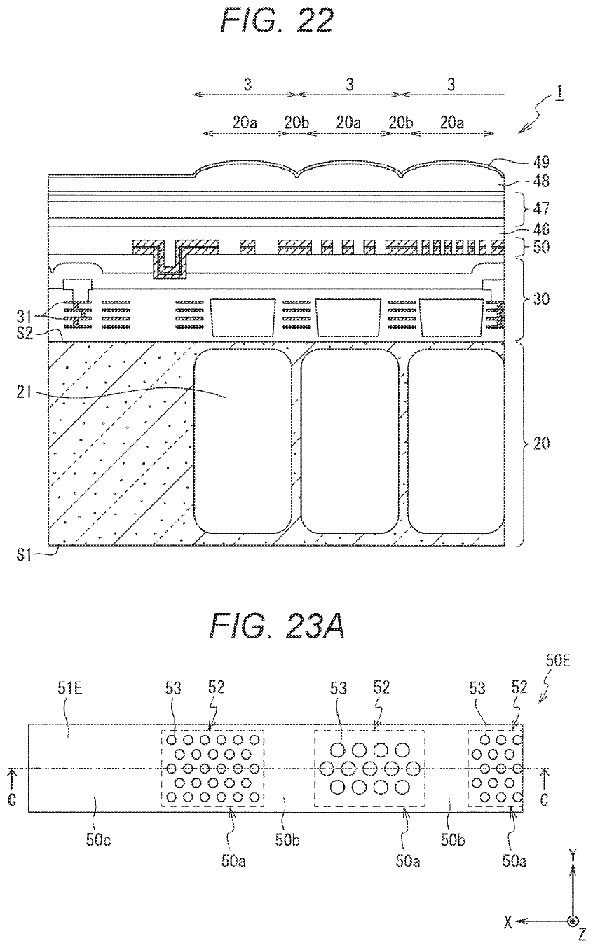

A sixth embodiment of the present technology illustrated in FIG. 22 will be described below. A photodetection device 1 according to the sixth embodiment is different from the photodetection device 1 according to the first embodiment described above in that the photodetection device 1 is a front-illuminated complementary metal oxide semiconductor (CMOS) image sensor, and other than that point, the configuration of the photodetection device 1 is basically similar to that of the photodetection device 1 according to the first embodiment described above. Note that the components already described will be denoted by the same reference signs, and the description thereof will be omitted.

As illustrated in FIG. 22, a photodetection device 1, which is a front-illuminated CMOS image sensor, includes a plasmonic filter 50 as an optical element including a conductor layer.

<<Main Effects of Sixth Embodiment

Even in the photodetection device 1 according to the sixth embodiment, effects similar to those of the photodetection device 1 according to the first embodiment described above can be obtained.

### SEVENTH EMBODIMENT

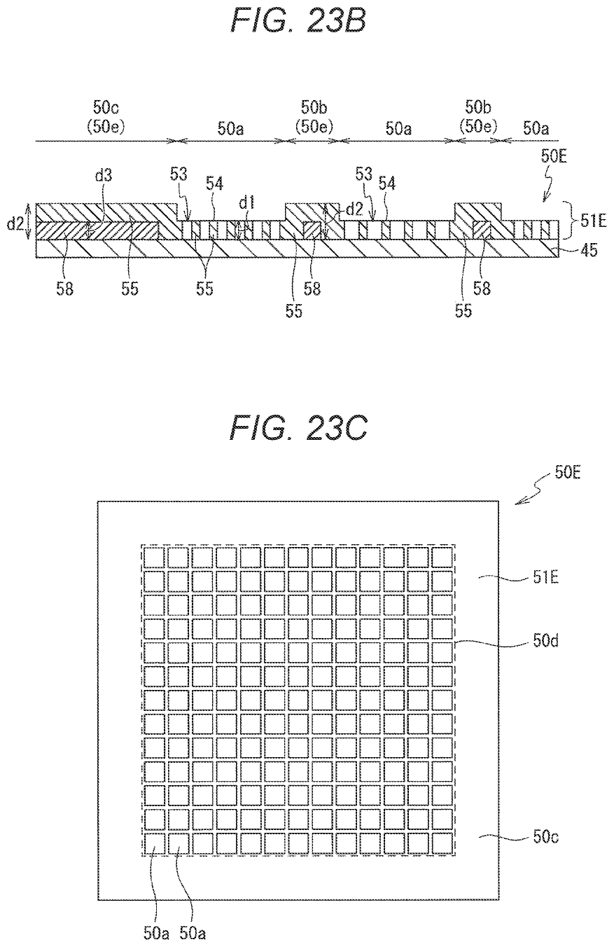

A seventh embodiment of the present technology illustrated in FIGS. 23A and 23B will be described below. A photodetection device 1 according to the seventh embodiment is different from the photodetection device 1 according to the first embodiment described above in that the thickness of a base material 51E is larger in a second region where opening arrays are not provided than in a first region where the opening arrays are provided. Other than that point, the configuration of the photodetection device 1 is basically similar to that of the photodetection device 1 according to the first embodiment described above. Note that the components already described will be denoted by the same reference signs, and the description thereof will be omitted.

<Plasmonic Filter>

A plasmonic filter 50E illustrated in FIGS. 23A and 23C is a color filter using surface plasmon resonance. The plasmonic filter 50 is an optical element including a conductor layer. The plasmonic filter 50E includes the base material 51E and opening arrays 52 formed in the base material 51E. Then, the opening arrays 52 each have a plurality of openings 53 arranged at an equal pitch in the base material 51E. Furthermore, the plasmonic filter 50E is arranged such that the opening arrays 52 overlap the photoelectric conversion regions 20a (photoelectric conversion unit 21) in plan view. This configuration can be understood by replacing the plasmonic filter 50 in FIG. 5A with the plasmonic filter 50E.

Furthermore, in base material 51E of the plasmonic filter 50E in plan view, regions where the opening arrays 52 are provided are referred to as opening regions 50a (first regions), and a region in which the opening arrays 52 are not provided between the adjacent opening regions 50a is referred to as a frame region 50b (second region). Furthermore, as illustrated in FIGS. 23B and 23C, a region that is adjacent to a region 50d provided with the plurality of opening regions 50a and that is not provided with the opening array 52 is referred to as a light shielding region 50c (second region). More specifically, the light shielding region 50c is provided so as to surround the region 50d provided with the plurality of opening regions 50a in plan view. Note that, in a case where it is not necessary to distinguish between the frame region 50b and the light shielding region 50c, these regions are not distinguished and may be referred to as a second region 50e. Here, since FIG. 23C schematically illustrates a plan view of the plasmonic filter 50E, the shape of the plasmonic filter 50E, the shape of the light shielding region 50c, the number of the opening regions 50a, and the like are not limited to those illustrated in FIG. 23C.

As illustrated in FIG. 23B, the thickness of the base material 51E is larger in the second region 50e than in the opening regions 50a (first regions). More specifically, the thickness of the second region 50e is d2, the thickness of the opening regions 50a is d1, and the thickness d2 of the second region 50e is larger than the thickness d1 of the opening region 50a (first regions) (d2>d1). For example, the thickness d2 of the second region 50e is, for example, 1.5 times or more and 3 times or less the thickness d1 of the opening regions 50a (first regions). Furthermore, for example, the thickness d2 may be twice the thickness d1.

The base material 51E includes a conductor layer. As illustrated in FIG. 23B, the base material 51E includes a first conductor layer 55 and a reinforcing layer 58 located between the first conductor layer 55 and a semiconductor layer 20. More specifically, the reinforcing layer 58 is in contact with the first conductor layer 55. Then, the opening regions 50a (first regions) include only the first conductor layer 55 out of the first conductor layer 55 and the reinforcing layer 58. More specifically, in the base material 51E provided in the opening regions 50a, portions 54 located between the adjacent openings 53 include only the first conductor layer 55 out of the first conductor layer 55 and the reinforcing layer 58. As described above, the opening regions 50a (first regions) of the base material 51E do not include the reinforcing layer 58. Furthermore, the second region 50e includes both the first conductor layer 55 and the reinforcing layer 58. Since the second region 50e includes the reinforcing layer 58 in addition to the first conductor layer 55, the thickness thereof is larger than that of the opening regions 50a.

As illustrated in FIG. 23B, the thickness of the first conductor layer 55 is d1, and the thickness of reinforcing layer 58 is d3. The thickness d2 of the second region 50e is obtained by summing the thickness d1 of the first conductor layer 55 and the thickness d3 of the reinforcing layer 58 (d2=d1+d3). The thickness d3 of the reinforcing layer 58 is preferably about 30 nm or more. Regarding the upper limit value of the thickness d3, for example, the thickness d3 may be set to 400 nm or less. Note that since the upper limit value of the thickness d3 also depends on the thickness of the base material 51E, the thickness d3 can also be obtained from the ratio described above with respect to the thickness of the base material 51E.

The material included in the first conductor layer 55 is as described in the first embodiment described above. As the material included in the reinforcing layer 58, the same material as the material described as the material included in the first conductor layer 55 in the above-described first embodiment, that is, a conductor can be used. In the seventh embodiment, it is assumed that the first conductor layer 55 and the reinforcing layer 58 include the same material. More specifically, as an example, both the first conductor layer 55 and the reinforcing layer 58 include an aluminum alloy obtained by adding 0.5 wt % of a body to aluminum.

<<Method of Manufacturing Photodetection Device>>

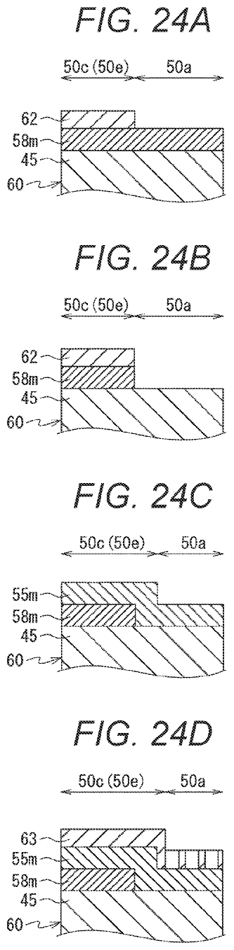

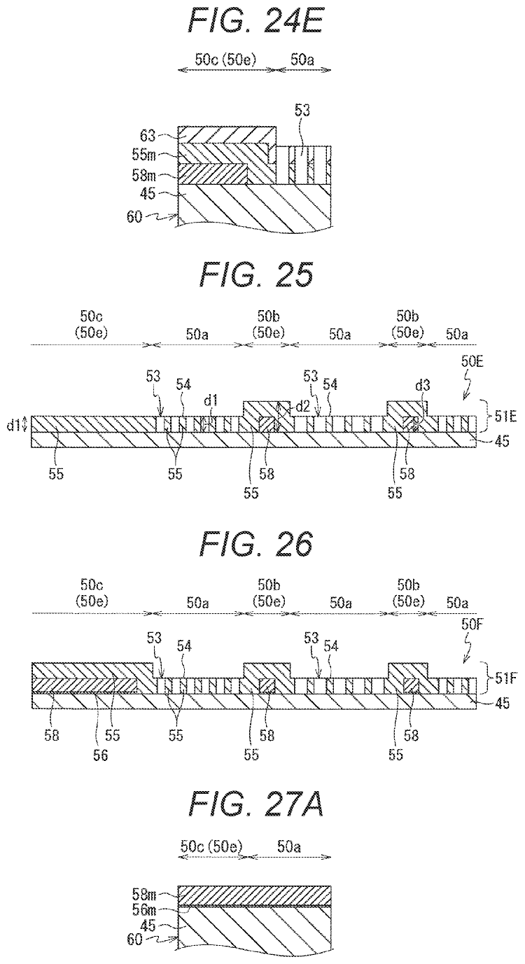

Hereinafter, a method of manufacturing the photodetection device 1 will be described with reference to FIGS. 24A to 24E. Note that, here, for simplification, a method of manufacturing the opening regions 50a as the first regions and the light shielding region 50c representing the second region 50e will be described. The method of manufacturing the frame region 50b is the same as the method of manufacturing the light shielding region 50c, and thus, is not described here.

First, as illustrated in FIG. 24A, a film 58m including the material included in the reinforcing layer 58 is formed on an insulating layer 45 of a prepared substrate 60 by using a method such as CVD or sputtering. Then, a resist pattern 62 is stacked on the film 58m using a known lithography technique. The resist pattern 62 is stacked so as to cover the light shielding region 50c.

Next, as illustrated in FIG. 24B, the exposed portions of the film 58m are removed by dry etching using the resist pattern 62 as a mask. The portions removed here is the film 58m in the parts corresponding to the opening regions 50a. Then, after the resist pattern 62 and the processing residues are removed by chemical cleaning, as illustrated in FIG. 24 C, the film 55m including the material included in the first conductor layer 55 is formed on both the opening regions 50a and the light shielding region 50c. Through this step, only the film 55m out of the film 58m and the film 55m is formed in the opening regions 50a, and both the film 58m and the film 55m are stacked in this order in the light shielding region 50c. Note that, after the resist pattern 62 and the processing residues are removed by chemical cleaning and before the film 55m is formed, reverse sputtering may be performed on the film 58m to remove the aluminum oxide layer formed by exposing the film 58m to the atmosphere.

Then, as illustrated in FIG. 24D, a resist pattern 63 is stacked on the film 55m using a known lithography technique. Then, as illustrated in FIG. 24E, using the resist pattern 63 as a mask, a film in portions exposed from the mask is removed by dry etching. More specifically, the film 55m stacked in the opening regions 50a is selectively removed to form the openings 53. Thereafter, the resist pattern 63 and the processing residues are removed by chemical cleaning. Thus, the plasmonic filter 50E is formed.

<<Main Effects of Seventh Embodiment>>

Even in the photodetection device 1 according to the seventh embodiment, effects similar to those of the photodetection device 1 according to the first embodiment described above can be obtained.

In addition, there have been cases where the stress migration that has already been described occurs in the vicinity of the boundary between the opening regions 50a and the frame region 50b and in the vicinity of the boundary between the opening regions 50 a and the light shielding region 50c.

In the plasmonic filter 50E according to the seventh embodiment of the present technology, the frame region 50b and the light shielding region 50c include the reinforcing layer 58 in addition to the first conductor layer 55 included in the opening regions 50a. As a result, the frame region 50b and the light shielding region 50c can be made thicker than the opening regions 50a. By setting the thicknesses of the frame region 50b and the light shielding region 50c to the total film thickness of the first conductor layer 55 and the reinforcing layer 58, the rigidity of the frame region 50b and the light shielding region 50c can be enhanced. Therefore, the occurrence of stress migration can be suppressed. This makes it possible to suppress defect formation and occurrence of distortion in the frame region 50b and the light shielding region 50c.

Furthermore, in the plasmonic filter 50E according to the seventh embodiment of the present technology, even in a case where stress migration occurs, transmission of light can be suppressed since the frame region 50b and the light shielding region 50c are formed thick.

Note that, in the seventh embodiment of the present technology, both the frame region 50b and the light shielding region 50c have the thickness d2, but as illustrated in FIG. 25, only the frame region 50b out of the frame region 50b and the light shielding region 50c may have the thickness d2, and the thickness of the light shielding region 50c may be d1. Moreover, only the light shielding region 50c out of the frame region 50b and the light shielding region 50c may have the thickness d2, and the thickness of the frame region 50b may be d1. That is, the second region 50e having the thickness d2 is at least one of the region (frame region 50b) between the adjacent opening regions 50a and the region (light shielding region 50c) surrounding the region 50d provided with the plurality of opening regions 50a.

[Modification 1 of Seventh Embodiment]

Modification 1 of the seventh embodiment of the present technology illustrated in FIG. 26 will be described below. A photodetection device 1 according to Modification 1 of the seventh embodiment is different from the photodetection device 1 according to the seventh embodiment described above in that a second region 50e of a base material 51F includes an intermediate layer in contact with a surface of a reinforcing layer 58 on a side opposite to a first conductor layer 55 side, and other than that point, the configuration of the photodetection device 1 is basically similar to that of the photodetection device 1 according to the seventh embodiment described above. Note that the components already described will be denoted by the same reference signs, and the description thereof will be omitted.

<Plasmonic Filter>

The plan view of a plasmonic filter 50F is similar to the plan view of FIG. 23A described above, and reference sign 50E may be read as reference sign 50F and reference sign 51E may be read as reference sign 51F. In addition, FIG. 26 is a view illustrating a cross-sectional configuration when viewed in a cross-sectional view taken along line C-C of FIG. 23A. The plasmonic filter 50F includes the base material 51F. The base material 51F includes the first conductor layer 55, the reinforcing layer 58, and an intermediate layer 56 in contact with a surface of the reinforcing layer 58 on a side opposite to the first conductor layer 55 side.

The intermediate layer 56 may include any high melting point metal having a higher melting point and higher rigidity than the first conductor layer 55 and the second conductor layer 57, a nitride of the high melting point metal, an oxide of the high melting point metal, a carbide of the high melting point metal, an alloy including the high melting point metal, a nitride of the alloy, an oxide of the alloy, and a carbide of the alloy. In addition, the high melting point metal is, for example, any of titanium (Ti), tantalum (Ta), tungsten (W), cobalt (Co), molybdenum (Mo), and hafnium (Hf).

Opening regions 50a (first regions) of the base material 51F include only the first conductor layer 55 out of the first conductor layer 55, the reinforcing layer 58, and the intermediate layer 56. That is, the opening regions 50a (first region) do not include the intermediate layer 56. Furthermore, the second region 50e of the base material 51F includes all the layers of the first conductor layer 55, the reinforcing layer 58, and the intermediate layer 56.

<<Method of Manufacturing Photodetection Device>>

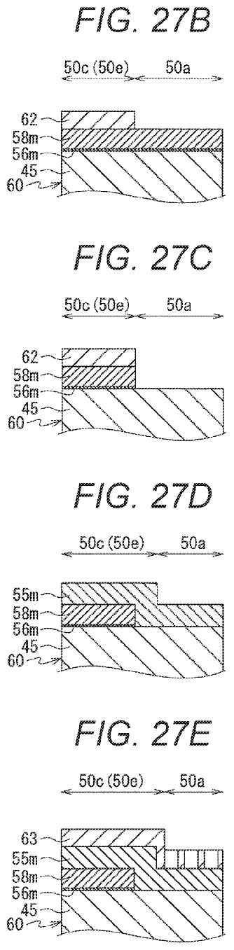

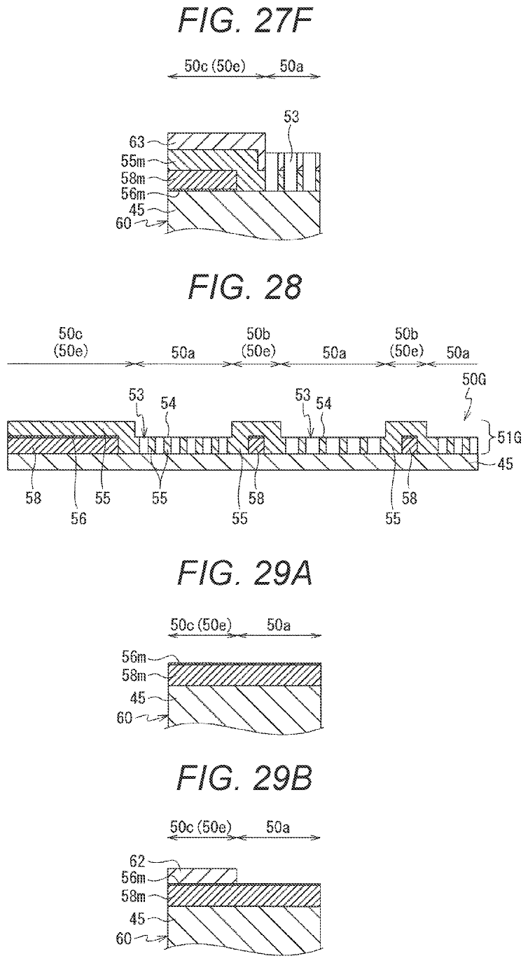

Hereinafter, a method of manufacturing the photodetection device 1 will be described with reference to FIGS. 27A to 27F. Note that, here, for simplification, a method of manufacturing the opening regions 50a as the first regions and the light shielding region 50c representing the second region 50e will be described.

First, as illustrated in FIG. 27A, a film 56m including the material included in the intermediate layer 56 and a film 58m including the material included in the reinforcing layer 58 are formed in this order on an insulating layer 45 of the prepared substrate 60. Then, as illustrated in FIG. 27B, a resist pattern 62 is stacked on the film 58m using a known lithography technique. The resist pattern 62 is stacked so as to cover the light shielding region 50c.

Next, as illustrated in FIG. 27C, from the film 58m to the film 56m in the exposed portions are removed by dry etching using the resist pattern 62 as a mask. The portions removed here is the film 58m and the film 56m in the parts corresponding to the opening regions 50a. Then, after the resist pattern 62 and the processing residues are removed by chemical cleaning, as illustrated in FIG. 27D, the film 55m including the material included in the first conductor layer 55 is formed on both the opening regions 50a and the light shielding region 50c. Through this step, only the film 55m out of the film 56m, film 58m, and the film 55m is formed in the opening regions 50a, and all the film 56m, the film 58m, and the film 55m are stacked in this order in the light shielding region 50c.

Then, as illustrated in FIG. 27E, a resist pattern 63 is stacked on the film 55m using a known lithography technique. Then, as illustrated in FIG. 27F, using the resist pattern 63 as a mask, a film in portions exposed from the mask is removed by dry etching. More specifically, the film 55m stacked in the opening regions 50a is selectively removed to form the openings 53. Thereafter, the resist pattern 63 and the processing residues are removed by chemical cleaning. Thus, the plasmonic filter 50F is formed.

<<Main Effects of Modification 1 of Seventh Embodiment>>

Even in the photodetection device 1 according to Modification 1 of the seventh embodiment, effects similar to those of the photodetection device 1 according to the seventh embodiment described above can be obtained.

Furthermore, in Modification 1 of the seventh embodiment of the present technology, the base material 51F of the frame region 50b and the light shielding region 50c has a thickness larger than that of the opening region 50a, and further the adhesion with the insulating layer 45 is enhanced since the base material 51F includes the intermediate layer 56 including a high melting point metal. Therefore, the occurrence of stress migration can be further suppressed as compared with the plasmonic filter 50E of the seventh embodiment. This makes it possible to suppress defect formation and occurrence of distortion in the frame region 50b and the light shielding region 50c.

[Modification 2 of Seventh Embodiment]

Modification 2 of the seventh embodiment of the present technology illustrated in FIG. 28 will be described below. A photodetection device 1 according to Modification 2 of the seventh embodiment is different from the photodetection device 1 according to the seventh embodiment described above in that a second region 50e of a base material 51G includes an intermediate layer 56 between a first conductor layer 55 and a reinforcing layer 58, and other than that point, the configuration of the photodetection device 1 is basically similar to that of the photodetection device 1 according to the seventh embodiment described above. Note that the components already described will be denoted by the same reference signs, and the description thereof will be omitted.

<Plasmonic Filter>

The plan view of a plasmonic filter 50G is similar to the plan view of FIG. 23A described above, and reference sign 50E may be read as reference sign 50G and reference sign 51E may be read as reference sign 51G. In addition, FIG. 28 is a view illustrating a cross-sectional configuration when viewed in a cross-sectional view taken along line C-C of FIG. 23A. The plasmonic filter 50G includes the base material 51G. The base material 51G includes a first conductor layer 55, the reinforcing layer 58, and an intermediate layer 56 provided between the first conductor layer 55 and the reinforcing layer 58. The material included in the intermediate layer 56 is desirably higher in rigidity than the material included in the first conductor layer 55 and the reinforcing layer 58. The intermediate layer 56 includes an oxide of a material included in the first conductor layer 55. In Modification 2 of the seventh embodiment, it is described that the intermediate layer 56 includes aluminum oxide (Al₂O₃).

Opening regions 50a (first regions) of the base material 51G include only the first conductor layer 55 out of the first conductor layer 55, the reinforcing layer 58, and the intermediate layer 56. That is, the opening regions 50a (first regions) of the base material 51G do not include the intermediate layer 56. In addition, the second region 50e of the base material 51G includes all the layers of the first conductor layer 55, the reinforcing layer 58, and the intermediate layer 56.

<<Method of Manufacturing Photodetection Device>>

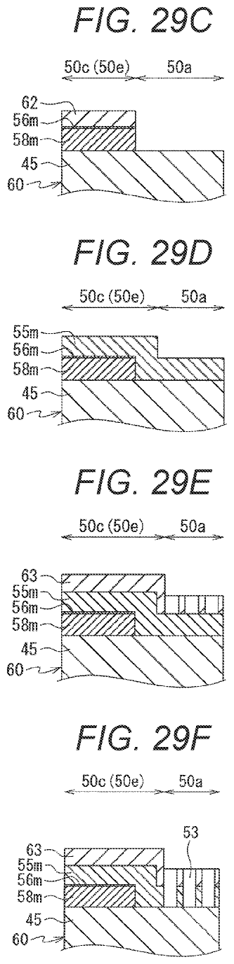

Hereinafter, a method of manufacturing the photodetection device 1 will be described with reference to FIGS. 29A to 29F. Note that, here, for simplification, a method of manufacturing the opening regions 50a as the first regions and the light shielding region 50c representing the second region 50e will be described.

First, as illustrated in FIG. 29A, a film 58m including the material included in the reinforcing layer 58 is formed on an insulating layer 45 of a prepared substrate 60. Then, a film 56m including the material included in the intermediate layer 56 is formed on the film 58m. More specifically, the film 58m is formed on the surface of the film 56m opposite to the surface on the insulating layer 45 side. The film 56m may be formed by oxidizing the surface of the film 58m opposite to the surface on the insulating layer 45 side. For example, the film 58m may be heated in an oxygen atmosphere, or the film 58m may be irradiated with oxygen plasma to form the film 56m. Furthermore, the film 56m may be formed by stacking aluminum oxide (Al₂O₃) on a surface of the film 58m opposite to the surface on the insulating layer 45 side by CVD or the like.

Next, as illustrated in FIG. 29B, a resist pattern 62 is stacked on the film 56m using a known lithography technique. The resist pattern 62 is stacked so as to cover the light shielding region 50c. Then, as illustrated in FIG. 29C, from the film 56m to the film 58m in the exposed portions are removed by dry etching using the resist pattern 62 as a mask. The portions removed here is the film 56m and the film 58m in the parts corresponding to the opening regions 50a.

Then, after the resist pattern 62 and the processing residues are removed by chemical cleaning, as illustrated in FIG. 29D, the film 55m including the material included in the first conductor layer 55 is formed on both the opening regions 50a and the light shielding region 50c. Through this step, only the film 55m out of the film 58m, film 56m, and the film 55m is formed in the opening regions 50a, and all the film 58m, the film 56m, and the film 55m are stacked in this order in the light shielding region 50c.

Then, as illustrated in FIG. 29E, a resist pattern 63 is stacked on the film 55m using a known lithography technique. Then, as illustrated in FIG. 29F, using the resist pattern 63 as a mask, a film in portions exposed from the mask is removed by dry etching. More specifically, the film 55m stacked in the opening regions 50a is selectively removed to form the openings 53. Thereafter, the resist pattern 63 and the processing residues are removed by chemical cleaning. Thus, the plasmonic filter 50G is formed.

<<Main Effects of Modification 2 of Seventh Embodiment>>

Even in the photodetection device 1 according to Modification 2 of the seventh embodiment, effects similar to those of the photodetection device 1 according to the seventh embodiment described above can be obtained.

Furthermore, in Modification 2 of the seventh embodiment of the present technology, the base material 51G of the frame region 50b and the light shielding region 50c has a thickness larger than that of the opening regions 50a, and further includes the intermediate layer 56 including aluminum oxide between the first conductor layer 55 and the reinforcing layer 58. Since aluminum oxide is thermally stable and is hardly deformed even at a high temperature, the occurrence of stress migration can be further suppressed as compared with the plasmonic filter 50E of the seventh embodiment. This makes it possible to suppress defect formation and occurrence of distortion in the frame region 50b and the light shielding region 50c.

Note that the intermediate layer 56 may include any high melting point metal having a higher melting point and higher rigidity than the first conductor layer 55 and the reinforcing layer 58, a nitride of the high melting point metal, an oxide of the high melting point metal, a carbide of the high melting point metal, an alloy including the high melting point metal, a nitride of the alloy, an oxide of the alloy, and a carbide of the alloy.

[Modification 3 of Seventh Embodiment]

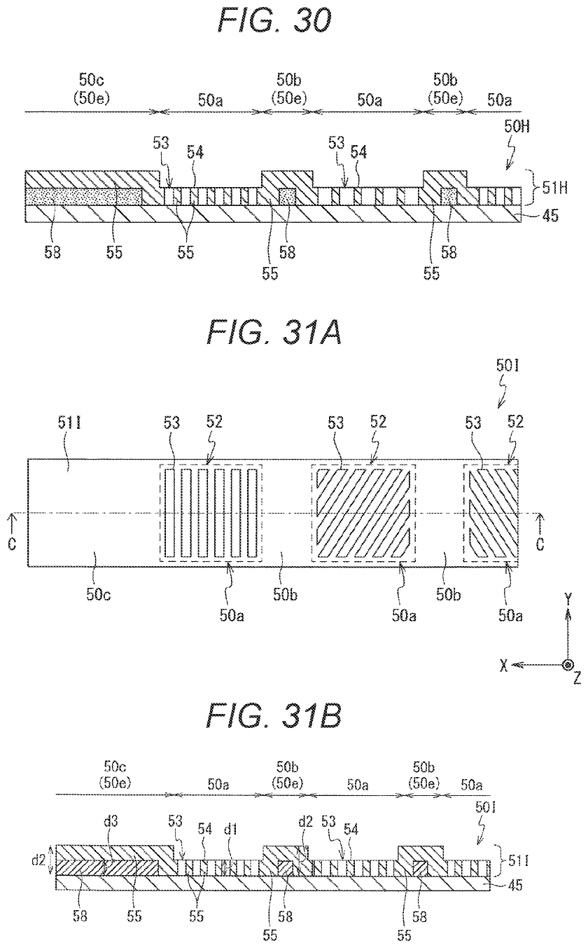

Modification 3 of the seventh embodiment of the present technology illustrated in FIG. 30 will be described below. A photodetection device 1 according to Modification 3 of the seventh embodiment is different from the photodetection device 1 according to the seventh embodiment described above in that a first conductor layer 55 and a reinforcing layer 58 of a base material 51H include different materials, and other than that point, the configuration of the photodetection device 1 is basically similar to that of the photodetection device 1 according to the seventh embodiment described above. Note that the components already described will be denoted by the same reference signs, and the description thereof will be omitted.

<Plasmonic Filter>

The plan view of a plasmonic filter 50H is similar to the plan view of FIG. 23A described above, and reference sign 50E may be read as reference sign 50H and reference sign 51E may be read as reference sign 51H. In addition, FIG. 30 is a view illustrating a cross-sectional configuration when viewed in a cross-sectional view taken along line C-C of FIG. 23A. The plasmonic filter 50H includes the base material 51H. The base material 51H includes the first conductor layer 55 and the reinforcing layer 58. The first conductor layer 55 and the reinforcing layer 58 include different materials. The first conductor layer 55 preferably includes a material that is easy to process, has good electrical conductivity, and is likely to cause a plasmon reaction. The reinforcing layer 58 includes a material that is higher in heat resistance (higher in melting point) and higher in rigidity than first conductor layer 55, for example. Therefore, the occurrence of migration can be suppressed.

Opening regions 50a (first regions) of the base material 51H include only the first conductor layer 55 out of the first conductor layer 55 and the reinforcing layer 58. Furthermore, a second region 50e of the base material 51H includes both the first conductor layer 55 and the reinforcing layer 58.

In Modification 3 of the seventh embodiment, as an example, the first conductor layer 55 includes aluminum, and the reinforcing layer 58 includes an aluminum alloy obtained by adding another metal to aluminum. The reinforcing layer 58 may include, for example, an alloy obtained by adding a metal such as copper to aluminum, or may include, for example, an aluminum alloy obtained by adding a high melting point metal, a nitride of a high melting point metal, an oxide of a high melting point metal, or a carbide of a high melting point metal to aluminum. Note that the high melting point metal is as described above.

<<Method of Manufacturing Photodetection Device>>

The method of manufacturing the photodetection device 1 according to Modification 3 of the seventh embodiment is similar to the steps illustrated in FIGS. 24A to 24E of the seventh embodiment. In FIGS. 24A to 24E, it may be read that the film 58m includes the above-described aluminum alloy, and the film 55m is synthesized with aluminum.

<<Main Effects of Modification 3 of Seventh Embodiment>

Even in the photodetection device 1 according to Modification 3 of the seventh embodiment, effects similar to those of the photodetection device 1 according to the seventh embodiment described above can be obtained.

In addition, in the photodetection device 1 according to Modification 3 of the seventh embodiment, the opening regions 50a (first regions) that actually function as a filter, and the reinforcing layer 58 included only in the second region 50e out of the opening regions 50a (first regions) and the second region 50e included in the second region 50e include a material having higher heat resistance and rigidity than the first conductor layer 55, so that it is possible to further suppress the occurrence of stress migration.

Furthermore, both efficiency of plasmon resonance in the opening regions 50a (first regions) and ease of processing can be achieved.

In Modification 3 of the seventh embodiment, as an example, an example has been described in which the first conductor layer 55 includes aluminum, and the reinforcing layer 58 includes an aluminum alloy to which aluminum or another metal is added, but the present invention is not limited thereto. The reinforcing layer 58 may include any material having higher heat resistance and rigidity than the first conductor layer 55. The first conductor layer 55 may include another metal, for example, aluminum alloy obtained by adding 0.5 wt % of a body to aluminum. In addition, for example, the reinforcing layer 58 may include a high melting point metal, a nitride of a high melting point metal, an oxide of a high melting point metal, or a carbide of a high melting point metal.

[Modification 4 of Seventh Embodiment]

Modification 4 of the seventh embodiment of the present technology illustrated in FIGS. 31A and 31B will be described below. A photodetection device 1 according to Modification 4 of the seventh embodiment is different from the photodetection device 1 according to the seventh embodiment described above in that the photodetection device 1 includes, instead of a plasmonic filter, a wire grid polarizer 501 as an optical element including a conductor layer, and other than that point, the configuration of the photodetection device 1 is basically similar to that of the photodetection device 1 according to the seventh embodiment described above. Note that the components already described will be denoted by the same reference signs, and the description thereof will be omitted.

<Wire Grid Polarizer>

The wire grid polarizer 50I includes a base material 51I. The base material 51I includes a first conductor layer 55 and a reinforcing layer 58. Opening regions 50a (first regions) of the base material 51H include only the first conductor layer 55 out of the first conductor layer 55 and the reinforcing layer 58. Furthermore, a second region 50e of the base material 51H includes both the first conductor layer 55 and the reinforcing layer 58.

Opening arrays 52 include openings 53 that are grooves penetrating the base material 51I in the thickness direction of a semiconductor layer 20. Furthermore, the opening arrays 52 each have a portion (in Modification 4 of the seventh embodiment of the present technology, the portion is referred to as a strip-shaped conductor) 54 including the base material 51I between adjacent two of the openings 53. The strip-shaped conductor 54 includes a first conductor layer 55.

<<Main Effects of Modification 4 of Seventh Embodiment>>

Even in the photodetection device 1 according to Modification 4 of the seventh embodiment, effects similar to those of the photodetection device 1 according to the seventh embodiment described above can be obtained.

In addition, the strip-shaped conductor 54 may have the same configuration as the strip-shaped conductor 54 described in the second embodiment.

[Modification 5 of Seventh Embodiment]

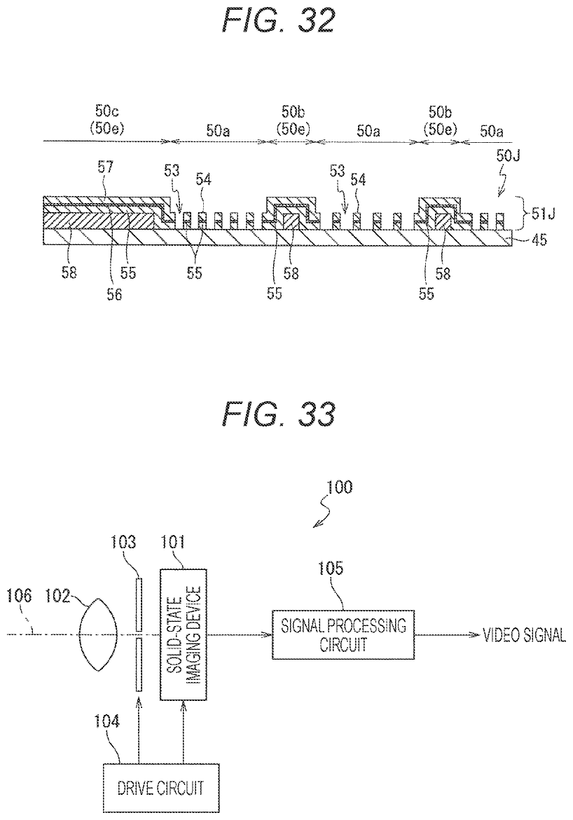

Modification 5 of the seventh embodiment of the present technology illustrated in FIG. 32 will be described below. A photodetection device 1 according to Modification 5 of the seventh embodiment is different from the photodetection device 1 according to the seventh embodiment described above in that a base material 51J includes a reinforcing layer 58, a first conductor layer 55, an intermediate layer 56, and a second conductor layer 57 in this order from a semiconductor layer 20 side, and other than that point, the configuration of the photodetection device 1 is basically similar to that of the photodetection device 1 according to the seventh embodiment described above. Note that the components already described will be denoted by the same reference signs, and the description thereof will be omitted.

<Plasmonic Filter>

Modification 5 of the seventh embodiment of the present technology is an embodiment obtained by combining the seventh embodiment with the first embodiment described above. The plan view of a plasmonic filter 50J is similar to the plan view of FIG. 23A described above, and reference sign 50E may be read as reference sign 50J and reference sign 51E may be read as reference sign 51J. In addition, FIG. 32 is a view illustrating a cross-sectional configuration when viewed in a cross-sectional view taken along line C-C of FIG. 23A. The plasmonic filter 50J includes the base material 51J. The base material 51J has a stacked structure including the reinforcing layer 58, the first conductor layer 55, the intermediate layer 56, and the second conductor layer 57 stacked in this order from the semiconductor layer 20 side. The second conductor layer 57 and the intermediate layer 56 are as described in the first embodiment described above.

Opening regions 50a (first regions) of the base material 51G include only the first conductor layer 55, the intermediate layer 56, and the second conductor layer 57 out of the stacked structure described above. That is, the opening regions 50a of the base material 51G do not include the reinforcing layer 58. In addition, a second region 50e of the base material 51J includes all the layers included in the stacked structure.

<<Method of Manufacturing Photodetection Device>>

A method of manufacturing the photodetection device 1 according to Modification 5 of the seventh embodiment will be described. The formation of the reinforcing layer 58 is as described in the seventh embodiment. Thereafter, steps similar to the steps described in the first embodiment may be performed.

<<Main Effects of Modification 5 of Seventh Embodiment>

Even in the photodetection device 1 according to Modification 5 of the seventh embodiment, effects similar to those of the photodetection device 1 according to the seventh embodiment described above can be obtained.

Furthermore, even in the photodetection device 1 according to Modification 5 of the seventh embodiment, effects similar to those of the photodetection device 1 according to the first embodiment described above can be obtained.

### EIGHTH EMBODIMENT

<Example of Application to Electronic Device>

Next, an electronic device according to an eighth embodiment of the present technology illustrated in FIG. 33 will be described. An electronic device 100 according to the eighth embodiment includes a photodetection device (solid-state imaging device) 101, an optical lens 102, a shutter device 103, a drive circuit 104, and a signal processing circuit 105. An electronic device 100 according to the eighth embodiment illustrates an embodiment in a case where the above-described photodetection device 1 is used as the photodetection device 101 for an electronic device (for example, a camera).

The optical lens (optical system) 102 forms an image of image light (incident light 106) from a subject on an imaging surface of the photodetection device 101. As a result, signal charges are accumulated in the photodetection device 101 over a certain period. The shutter device 103 controls a light irradiation period and a light shielding period for the photodetection device 101. The drive circuit 104 supplies a drive signal for controlling a transfer operation of the photodetection device 101 and a shutter operation of the shutter device 103. A signal of the photodetection device 101 is transferred in response to a drive signal (timing signal) supplied from the drive circuit 104. The signal processing circuit 105 performs various types of signal processing on a signal (pixel signal) output from the photodetection device 101. A video signal subjected to the signal processing is stored in a storage medium such as a memory or output to a monitor.

With the configuration described above, in the electronic device 100 according to the eighth embodiment, the occurrence of the stress migration of the photodetection device 101 can be suppressed, so that the image quality of the video signal can be improved.

Note that the electronic device 100 to which the photodetection device 1 according to any one of the first to seventh embodiments can be applied is not limited to a camera, and the photodetection device 1 can also be applied to other electronic devices. For example, the photodetection device 1 may be applied to an imaging device such as a camera module for a mobile device such as a mobile phone.

Furthermore, in the eighth embodiment, as the photodetection device 101, the photodetection device 1 according to any one of the first to seventh embodiments and the modifications thereof, or the photodetection device 1 according to a combination of at least two of the first to seventh embodiments and the modifications thereof can be used as the electronic device.

### OTHER EMBODIMENTS

As described above, the present technology has been described by way of the first to eighth embodiments, but it should not be understood that the description and drawings constituting a part of this disclosure limit the present technology. Various alternative embodiments, examples, and operation techniques will be apparent to those skilled in the art from this disclosure.

For example, at least two of the first to seventh embodiments and the modifications thereof may be combined. More specifically, for example, the GMR color filter described in the third embodiment can be applied to the optical elements described in the seventh embodiment and the modifications thereof, and various combinations are possible in accordance with the respective technical ideas.

As described above, it is a matter of course that the present technology includes various embodiments and the like not described herein. Therefore, the technical scope of the present technology is defined only by the matters used to define the invention described in the claims considered appropriate from the above description.

Furthermore, the present technology is applicable to any photodetection device including not only the above-described solid-state imaging device as an image sensor but also a ranging sensor also called a time of flight (ToF) sensor that measures a distance, and the like. The distance measuring sensor is a sensor that emits irradiation light toward an object, detects reflected light that is the irradiation light returning by the reflection on a surface of the object, and calculates a distance to the object on the basis of a flight time from emission of the irradiation light to reception of the reflected light. As a light receiving pixel structure of the distance measuring sensor, the above-described structure of the pixel 2 can be adopted.

Furthermore, the effects described herein are merely illustrative and not restrictive, and may have additional effects.

Note that the present technology may have the following configurations.

(1)

A photodetection device including:
a semiconductor layer including a photoelectric conversion unit;
an optical element that includes a base material and an opening array formed in the base material, supplies light selected by the opening array to the photoelectric conversion unit, and is arranged so as to overlap the photoelectric conversion unit in plan view, in which the base material includes a stacked structure including a first conductor layer, an intermediate layer, and a second conductor layer in this order from the semiconductor layer side.

(2)

The photodetection device according to (1), in which a material included in the intermediate layer is higher in rigidity than a material included in the first conductor layer and the second conductor layer.

(3)

The photodetection device according to (1) or (2), in which the intermediate layer includes any of an oxide of a material included in the first conductor layer, a high melting point metal having a higher melting point than that of the first conductor layer and the second conductor layer, a nitride of the high melting point metal, an oxide of the high melting point metal, a carbide of the high melting point metal, an alloy including the high melting point metal, a nitride of the alloy, an oxide of the alloy, and a carbide of the alloy.

(4)

The photodetection device according to (3), in which the high melting point metal is titanium, tantalum, tungsten, cobalt, molybdenum, or hafnium.

(5)

The photodetection device according to any one of (1) to (4), in which each of the first conductor layer and the second conductor layer includes a metal material or an organic conductive film.

(6)

The photodetection device according to any one of (1) to (5), in which the intermediate layer has a thickness of 1 nm or more and 50 nm or less.

(7)

The photodetection device according to any one of (1) to (6), in which the optical element is any of a color filter using surface plasmon resonance, a wire grid polarizer, and a GMR color filter.

(8)

The photodetection device according to any one of (1) to (6), in which the optical element is a color filter using surface plasmon resonance, and at least the first conductor layer out of the first conductor layer and the second conductor layer includes a first portion that is at least 50 nm in a thickness direction from a surface at a side opposite to the intermediate layer side and in which a material included in the intermediate layer is not diffused, and a second portion that is in contact with the intermediate layer and in which the material included in the intermediate layer is diffused.

(9)

An electronic device including: a photodetection device; and an optical system that causes the photodetection device to form an image of image light from a subject,
in which the photodetection device includes:
a semiconductor layer including a photoelectric conversion unit; and
an optical element that includes a base material and an opening array formed in the base material, supplies light selected by the opening array to the photoelectric conversion unit, and is arranged to overlap the photoelectric conversion unit in plan view, and
the base material has a stacked structure including a first conductor layer, an intermediate layer, and a second conductor layer in this order from the semiconductor layer side.

(10)

A photodetection device including:
a semiconductor layer including a photoelectric conversion unit; and
an optical element that includes a base material including a conductor layer and an opening array formed in the base material, supplies light selected by the opening array to the photoelectric conversion unit, and is arranged to overlap the photoelectric conversion unit in plan view,
in which the base material includes a first region in which the opening array is provided and a second region in which the opening array is not provided in plan view, and
the base material has a thickness larger in the second region than in the first region.

(11)

The photodetection device according to (10), in which a thickness of the second region has is 1.5 times or more and 3 times or less a thickness of the first region.

(12)

The photodetection device according to (10) or (11),
in which the base material includes a first conductor layer and a reinforcing layer located between the first conductor layer and the semiconductor layer, and
the first region includes only the first conductor layer out of the first conductor layer and the reinforcing layer, and
the second region includes both the first conductor layer and the reinforcing layer.

(13)

The photodetection device according to (12), in which the reinforcing layer has a thickness of 30 nm or more and 400 nm or less.

(14)

The photodetection device according to (12) or (13),
in which the second region includes an intermediate layer in contact with a surface of the reinforcing layer on a side opposite to the first conductor layer side, and the first region does not include the intermediate layer.

(15)

The photodetection device according to (12) or (13), in which the second region includes an intermediate layer between the first conductor layer and the reinforcing layer, and the first region does not include the intermediate layer.

(16)

The photodetection device according to (14) or (15), in which a material included in the intermediate layer is higher in rigidity than a material included in the first conductor layer and the reinforcing layer.

(17)

The photodetection device according to (12) or (13), in which the reinforcing layer and the first conductor layer include different materials, and a material included in the reinforcing layer is higher in rigidity than a material included in the first conductor layer.

(18)

The photodetection device according to (10), (11), (13), or (17),
in which the base material has a stacked structure including a reinforcing layer, a first conductor layer, an intermediate layer, and a second conductor layer in this order from the semiconductor layer side,
the base material included in the second region includes all the layers included in the stacked structure, and
the base material included in the first region includes only the first conductor layer, the intermediate layer, and the second conductor layer in the stacked structure.

(19)

The photodetection device according to any one of (10) to (18), in which the second region is at least one of a frame region between adjacent ones of the opening arrays and a light shielding region surrounding a region where a plurality of the opening arrays is provided.

(20)

An electronic device including: a photodetection device; and an optical system that causes the photodetection device to form an image of image light from a subject,
in which the photodetection device includes:
a semiconductor layer including a photoelectric conversion unit; and
an optical element that includes a base material including a conductor layer and an opening array formed in the base material, supplies light selected by the opening array to the photoelectric conversion unit, and is arranged to overlap the photoelectric conversion unit in plan view,
the base material includes a first region in which the opening array is provided and a second region in which the opening array is not provided in plan view, and
the base material has a thickness larger in the second region than in the first region.

### REFERENCE SIGNS LIST

1 Photodetection device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Reading circuit
20 Semiconductor layer
20a Photoelectric conversion region
20b Element isolation unit
20a Photoelectric conversion region (element formation region)
20b, 20b1 Element isolation unit
20c Groove
21 Photoelectric conversion unit
30 Wiring layer
31 Wiring
41 Support substrate
42, 42a, 42b Fixed charge film
43, 45, 46 Insulating layer
44 Light-shielding metal
47 Passivation film
48 On-chip lens
50, 50A, 50B, 50E, 50F, 50G, 50H, 50J Plasmonic filter
50a Opening region (first region)
50b Frame region
50c Light shielding region
50d Region
50e Second region
50C, 50I Wire grid polarizer
50D GMR color filter
51, 51C, 51D, 51E, 51F, 51G, 51H, 51I, 51J Base material
51S1 Upper surface
51S2 Lower surface
52 Opening array
53 Opening
54 Strip-shaped conductor
55 First conductor layer
55a First portion
55b Second portion
56 Intermediate layer
57 Second conductor layer
57a First portion
57b Second portion
58 Reinforcing layer
59D Waveguide
60 Substrate
100 Electronic device
101 Photodetection device
102 Optical system (optical lens)
103 Shutter device
104 Drive circuit
105 Signal processing circuit
106 Incident light

What is claimed is:

1. A photodetection device, comprising:
a semiconductor layer including a photoelectric conversion unit; and
an optical element that includes a base material and an opening array formed in the base material, supplies light selected by the opening array to the photoelectric conversion unit, and is arranged so as to overlap the photoelectric conversion unit in plan view,
wherein the base material has a stacked structure including a first conductor layer, an intermediate layer, and a second conductor layer in this order from the semiconductor layer side.

2. The photodetection device according to claim 1, wherein a material included in the intermediate layer is higher in rigidity than a material included in the first conductor layer and the second conductor layer.

3. The photodetection device according to claim 1, wherein the intermediate layer includes any of an oxide of a material included in the first conductor layer, a high melting point metal having a higher melting point than that of the first conductor layer and the second conductor layer, a nitride of the high melting point metal, an oxide of the high melting point metal, a carbide of the high melting point metal, an alloy including the high melting point metal, a nitride of the alloy, an oxide of the alloy, and a carbide of the alloy.

4. The photodetection device according to claim 3, wherein the high melting point metal is titanium, tantalum, tungsten, cobalt, molybdenum, or hafnium.

5. The photodetection device according to claim 1, wherein each of the first conductor layer and the second conductor layer includes a metal material or an organic conductive film.

6. The photodetection device according to claim 1, wherein the intermediate layer has a thickness of 1 nm or more and 50 nm or less.

7. The photodetection device according to claim 1, wherein the optical element is any of a color filter using surface plasmon resonance, a wire grid polarizer, and a GMR color filter.

8. The photodetection device according to claim 1,
wherein the optical element is a color filter using surface plasmon resonance, and
at least the first conductor layer out of the first conductor layer and the second conductor layer includes a first portion that is at least 50 nm in a thickness direction from a surface at a side opposite to the intermediate layer side and in which a material included in the intermediate layer is not diffused, and a second portion that is in contact with the intermediate layer and in which the material included in the intermediate layer is diffused.

9. An electronic device, comprising:
a photodetection device; and
an optical system that causes the photodetection device to form an image of image light from a subject,
wherein the photodetection device includes:
a semiconductor layer including a photoelectric conversion unit; and
an optical element that includes a base material and an opening array formed in the base material, supplies light selected by the opening array to the photoelectric conversion unit, and is arranged to overlap the photoelectric conversion unit in plan view, and
the base material has a stacked structure including a first conductor layer, an intermediate layer, and a second conductor layer in this order from the semiconductor layer side.

10. A photodetection device, comprising:
a semiconductor layer including a photoelectric conversion unit; and
an optical element that includes a base material including a conductor layer and an opening array formed in the base material, supplies light selected by the opening array to the photoelectric conversion unit, and is arranged to overlap the photoelectric conversion unit in plan view,
wherein the base material includes a first region in which the opening array is provided and a second region in which the opening array is not provided in plan view, and
the base material has a thickness larger in the second region than in the first region.

11. The photodetection device according to claim 10, wherein a thickness of the second region has is 1.5 times or more and 3 times or less a thickness of the first region.

12. The photodetection device according to claim 10,
wherein the base material includes a first conductor layer and a reinforcing layer located between the first conductor layer and the semiconductor layer, and
the first region includes only the first conductor layer out of the first conductor layer and the reinforcing layer, and
the second region includes both the first conductor layer and the reinforcing layer.

13. The photodetection device according to claim 12, wherein the reinforcing layer has a thickness of 30 nm or more and 400 nm or less.

14. The photodetection device according to claim 12,
wherein the second region includes an intermediate layer in contact with a surface of the reinforcing layer on a side opposite to the first conductor layer side, and
the first region does not include the intermediate layer.

15. The photodetection device according to claim 12, wherein the second region includes an intermediate layer between the first conductor layer and the reinforcing layer, and the first region does not include the intermediate layer.

16. The photodetection device according to claim 14, wherein a material included in the intermediate layer is higher in rigidity than a material included in the first conductor layer and the reinforcing layer.

17. The photodetection device according to claim 12, wherein the reinforcing layer and the first conductor layer include different materials, and a material included in the reinforcing layer is higher in rigidity than a material included in the first conductor layer.

18. The photodetection device according to claim 10,
wherein the base material has a stacked structure including a reinforcing layer, a first conductor layer, an intermediate layer, and a second conductor layer in this order from the semiconductor layer side,
the base material included in the second region includes all the layers included in the stacked structure, and
the base material included in the first region includes only the first conductor layer, the intermediate layer, and the second conductor layer in the stacked structure.

19. The photodetection device according to claim 10, wherein the second region is at least one of a frame region between adjacent ones of the opening arrays and a light shielding region surrounding a region where a plurality of the opening arrays is provided.

20. An electronic device, comprising:
a photodetection device; and
an optical system that causes the photodetection device to form an image of image light from a subject,
wherein the photodetection device includes:
a semiconductor layer including a photoelectric conversion unit; and
an optical element that includes a base material including a conductor layer and an opening array formed in the base material, supplies light selected by the opening array to the photoelectric conversion unit, and is arranged to overlap the photoelectric conversion unit in plan view,
the base material includes a first region in which the opening array is provided and a second region in which the opening array is not provided in plan view, and
the base material has a thickness larger in the second region than in the first region.
